(19) United States
(12) Patent Application Publication
(10) Pub. No.: US 2024/0186106 A1
(43) Pub. Date: Jun. 6, 2024

(54) ON SYSTEM SELF-DIAGNOSIS AND SELF-CALIBRATION TECHNIQUE FOR CHARGED PARTICLE BEAM SYSTEMS

(71) Applicant: ASML Netherlands B.V., Veldhoven (NL)

(72) Inventors: Yongxin WANG, San Ramon, CA (US); Bruno LA FONTAINE, Pleasanton, CA (US)

(73) Assignee: ASML Netherlands B.V., Veldhoven (NL)

(21) Appl. No.: 18/284,839

(22) PCT Filed: Mar. 3, 2022
(86) PCT No.: PCT/EP2022/055351

§ 371 Date: Sep. 28, 2023

Related U.S. Application Data
(60) Provisional application No. 63/181,231, filed on Apr. 28, 2021.
(60) Provisional application No. 63/168,170, filed on Mar. 30, 2021.

(51) Int. Cl. H01J 37/24; H01J 37/244

(52) U.S. Cl. CPC H01J 37/24; H01J 37/244

(57) ABSTRACT

An improved method of performing a self-diagnosis of a charged particle inspection system is disclosed. An improved method comprises triggering a self-diagnosis based on output data of the charged particle inspection system; in response to the triggering of the self-diagnosis, receiving diagnostic data of a sub-system of the charged particle inspection system; identifying an issue associated with the output data based on the diagnostic data of the sub-system; and generating a control signal to adjust an operation parameter of the sub-system according to the identified issue.

### CROSS-REFERENCE TO RELATED APPLICATIONS

This application claims priority of U.S. application 63/168,170 which was filed on Mar. 30, 2021 and U.S. application 63/181,231 which was filed on Apr. 28, 2021 which is incorporated herein in its entirety by reference.

### FIELD

The description herein relates to on system self-diagnosis and self-calibration techniques for charged particle beam systems.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, accuracy and yield in defect detection become more important.

When performance issues are discovered in the inspection systems, it is difficult to determine root causes thereof because inspection systems consist of many sub-systems or components that may cause the performance issues. As inspection systems get more complicated, system down time for debugging becomes longer and therefore efficiency of a chip manufacturing process may be degraded. Improvements in performance diagnosis and calibration in inspection systems are thus desired.

### SUMMARY

The embodiments provided herein disclose a particle beam inspection apparatus, and more particularly, an inspection apparatus using one or more charged particle beams.

In some embodiments, a method of performing a self-diagnosis of a charged particle inspection system is provided. The method comprises: triggering a self-diagnosis based on output data of the charged particle inspection system; in response to the triggering of the self-diagnosis, receiving diagnostic data of a sub-system of the charged particle inspection system; identifying an issue associated with the output data based on the diagnostic data of the sub-system; and generating a control signal to adjust an operation parameter of the sub-system according to the identified issue.

In some embodiments, an apparatus of performing a self-diagnosis of a charged particle inspection system is provided. The apparatus comprises: a memory storing a set of instructions; and at least one processor configured to execute the set of instructions to cause the apparatus to perform: triggering a self-diagnosis based on output data of the charged particle inspection system; in response to the triggering of the self-diagnosis, receiving diagnostic data of a sub-system of the charged particle inspection system; identifying an issue associated with the output data based on the diagnostic data of the sub-system; and generating a control signal to adjust an operation parameter of the sub-system according to the identified issue.

In some embodiments, a non-transitory computer readable medium that stores a set of instructions that is executable by at least one processor of a computing device to cause the computing device to perform a method of performing a self-diagnosis of a charged particle inspection system is provided. The method comprises: triggering a self-diagnosis based on output data of the charged particle inspection system; in response to the triggering of the self-diagnosis, receiving diagnostic data of a sub-system of the charged particle inspection system; identifying an issue associated with the output data based on the diagnostic data of the sub-system; and generating a control signal to adjust an operation parameter of the sub-system according to the identified issue.

In some embodiments, a method of estimating a bandwidth of a detection channel of a charged particle inspection system is provided. The method comprises: acquiring multiple inspection images of a sample, the multiple inspection images being obtained using different average indexes; determining a maximum average index from which an increase of an average index does not contribute to inspection image sharpness; acquiring a first signal corresponding to a first inspection image among the multiple inspection images and a second signal corresponding to a second inspection image among the multiple inspection images, wherein the first inspection image is obtained using average index 1 and the second inspection is obtained using the maximum average index; acquiring a first signal spectrum of the first signal and a second signal spectrum of the second signal; acquiring a shifted second signal spectrum with a ratio of the maximum average index, wherein the shifted second signal spectrum and the first signal spectrum are distributed in a same frequency range; and acquiring an estimated partial frequency response of the detection channel based on the first signal spectrum and the shifted second signal spectrum.

In some embodiments, an apparatus estimating a bandwidth of a detection channel of a charged particle inspection system is provided. The apparatus comprises: a memory storing a set of instructions; and at least one processor configured to execute the set of instructions to cause the apparatus to perform: acquiring multiple inspection images of a sample, the multiple inspection images being obtained using different average indexes; determining a maximum average index from which an increase of an average index does not contribute to inspection image sharpness; acquiring a first signal corresponding to a first inspection image among the multiple inspection images and a second signal corresponding to a second inspection image among the multiple inspection images, wherein the first inspection image is obtained using average index 1 and the second inspection is obtained using the maximum average index; acquiring a first signal spectrum of the first signal and a second signal spectrum of the second signal; acquiring a shifted second signal spectrum with a ratio of the maximum average index, wherein the shifted second signal spectrum and the first signal spectrum are distributed in a same frequency range; and acquiring an estimated partial frequency response of the detection channel based on the first signal spectrum and the shifted second signal spectrum.

In some embodiments, a non-transitory computer readable medium that stores a set of instructions that is executable by at least one processor of a computing device to cause the computing device to perform a method of estimating a bandwidth of a detection channel of a charged particle inspection system is provided. The method comprises: acquiring multiple inspection images of a sample, the multiple inspection images being obtained using different average indexes; determining a maximum average index from which an increase of an average index does not contribute to inspection image sharpness; acquiring a first signal corresponding to a first inspection image among the multiple inspection images and a second signal corresponding to a second inspection image among the multiple inspection images, wherein the first inspection image is obtained using average index 1 and the second inspection is obtained using the maximum average index; acquiring a first signal spectrum of the first signal and a second signal spectrum of the second signal; acquiring a shifted second signal spectrum with a ratio of the maximum average index, wherein the shifted second signal spectrum and the first signal spectrum are distributed in a same frequency range; and acquiring an estimated partial frequency response of the detection channel based on the first signal spectrum and the shifted second signal spectrum.

In some embodiments, an apparatus of performing a self-diagnosis of a charged particle inspection system is provided. The apparatus comprises a memory storing a set of instructions; and at least one processor configured to execute the set of instructions to cause the apparatus to perform: triggering a self-diagnosis based on output data of the charged particle inspection system; in response to the triggering of the self-diagnosis, receiving diagnostic data of a detection channel of the charged particle inspection system; estimating a bandwidth of the detection channel based on the diagnostic data; and generating a control signal to adjust an operation parameter associated with the detection channel based on the estimated bandwidth.

It is to be understood that both the foregoing general description and the following detailed description are exemplary and explanatory only and are not restrictive of the disclosed embodiments, as may be claimed.

### BRIEF DESCRIPTION OF THE DRAWINGS

The above and other aspects of the present disclosure will become more apparent from the description of exemplary embodiments, taken in conjunction with the accompanying drawings.

FIG. 1 is a diagrammatic representation of an exemplary electron beam inspection (EBI) system, consistent with embodiments of the present disclosure.

FIGS. 2A and 2B are diagrams illustrating a charged particle beam apparatus that may be an example of an electron beam tool, consistent with embodiments of the present disclosure.

FIGS. 3A-3C are diagrammatic representations of an exemplary structure of a detector, consistent with embodiments of the present disclosure.

FIG. 4 is a diagram illustrating an exemplary surface of a detector, consistent with embodiments of the present disclosure.

FIG. 5 is a diagrammatic representation of a detection channel, consistent with embodiments of the present disclosure.

FIG. 6 is a block diagram of an example self-diagnosis and calibration system, consistent with embodiments of the present disclosure.

FIG. 7 is a block diagram of an example detection channel bandwidth estimation apparatus, consistent with embodiments of the present disclosure.

FIGS. 8A-8G illustrates a process of estimating a detection channel bandwidth, consistent with embodiments of the present disclosure.

FIG. 9 illustrates a flow chart of an example self-diagnosis and calibration method, consistent with embodiments of the present disclosure.

FIG. 10 illustrates a flow chart of an example detection channel bandwidth estimation method, consistent with embodiments of the present disclosure.

### DETAILED DESCRIPTION

Reference will now be made in detail to exemplary embodiments, examples of which are illustrated in the drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses, systems, and methods consistent with aspects related to subject matter that may be recited in the appended claims.

Electronic devices are constructed of circuits formed on a piece of silicon called a substrate. Many circuits may be formed together on the same piece of silicon and are called integrated circuits or ICs. With advancements in technology, the size of these circuits has decreased dramatically so that many more of them can fit on the substrate. For example, an IC chip in a smart phone can be as small as a fingernail and yet may include over 2 billion transistors, the size of each transistor being less than 1/1,000th the width of a human hair.

Making these extremely small ICs is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). A SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur. To enhance throughput (e.g., the number of samples processed per hour), it is desirable to conduct inspection as quickly as possible.

An image of a wafer may be formed by scanning a primary beam of a SEM system (e.g., a “probe” beam) over the wafer and collecting particles (e.g., secondary electrons) generated from the wafer surface at a detector. Secondary electrons may form a beam (a “secondary beam”) that is directed toward the detector. Secondary electrons landing on the detector may cause electrical signals (e.g., current, charge, voltage, etc.) to be generated in the detector. These signals may be output from the detector and may be processed by an image processor to form the image of the sample.

Typically, the detection process involves measuring the magnitude of an electrical signal generated when electrons land on the detector. In another approach, electron counting may be used, in which a detector may count individual electron arrival events as they occur. In either approach, intensity of the secondary beam may be determined based on electrical signals generated in the detector that vary in proportion to the intensity of the secondary beam.

Overall performance of an inspection system such as a SEM can be affected by various sub-systems or components included in the inspection system. For example, one or more sub-systems or parameters of an inspection system may affect an inspection image quality, e.g., sharpness or blurriness. Therefore, when a SEM generates a low-quality SEM image (e.g., blurred SEM image), a process of identifying what caused the inspection image degradation among various possible causes is performed for debugging. As an inspection system gets more complicated, it is more difficult to locate a root cause of a malfunction or performance failure of the inspection system. Thereby, an inspection system may suffer from longer down time for debugging and thus efficiency of a chip manufacturing process can be degraded.

Further, a detection channel bandwidth can affect inspection image quality and thus overall performance of an inspection system. However, due to complexity of a detection channel including sensing elements, analog signal path, or converter, etc., it is difficult to have an accurate bandwidth measurement of the detection channel without building a dedicated test setup that may simulate operation environments of the detection channel. Therefore, improvements in estimating a bandwidth of a detection channel of an inspection system is desired.

Embodiments of the disclosure may provide an on-system self-diagnosis technique for a charged particle inspection system. According to some embodiments of the present disclosure, inspection system performance can be maintained based on an on-system self-diagnosis and self-calibration mechanism. According to some embodiments of the present disclosure, a self-diagnosis and self-calibration can be performed for any sub-systems of a charged particle inspection system. According to some embodiments of the present disclosure, a self-diagnosis and self-calibration can be performed for one or more sub-systems of a charged particle inspection system. According to some embodiments of the present disclosure, performance diagnosis or calibration can be performed on data collected by a hardware component embedded in an inspection system without using an external test equipment. Embodiments of the disclosure may also provide a detection channel bandwidth estimation technique that does not use a dedicated test setup. According to some embodiments of the present disclosure, a detection channel bandwidth can be estimated based on inspection images and data collected by a hardware component embedded in an inspection system.

Objects and advantages of the disclosure may be realized by the elements and combinations as set forth in the embodiments discussed herein. However, embodiments of the present disclosure are not necessarily required to achieve such exemplary objects or advantages, and some embodiments may not achieve any of the stated objects or advantages.

Without limiting the scope of the present disclosure, some embodiments may be described in the context of providing detection systems and detection methods in systems utilizing electron beams (“e-beams”). However, the disclosure is not so limited. Other types of charged particle beams may be similarly applied. Furthermore, systems and methods for detection may be used in other imaging systems, such as optical imaging, photon detection, x-ray detection, ion detection, etc. Additionally, the term “beamlet” may refer to a constituent part of a beam or a separate beam extracted from an original beam. The term “beam” may refer to beams or beamlets.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C.

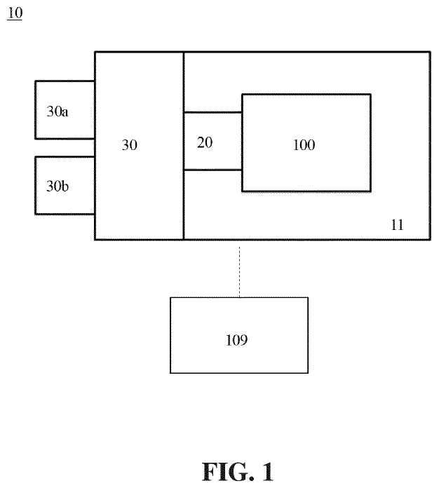

Reference is now made to FIG. 1, which illustrates an exemplary electron beam inspection (EBI) system 10 that may be used for wafer inspection, consistent with embodiments of the present disclosure. As shown in FIG. 1, EBI system 10 includes a main chamber 11, a load/lock chamber 20, an electron beam tool 100 (e.g., a scanning electron microscope (SEM)), and an equipment front end module (EFEM) 30. Electron beam tool 100 is located within main chamber 11 and may be used for imaging. EFEM 30 includes a first loading port 30a and a second loading port 30b. EFEM 30 may include additional loading ports. First loading port 30a and second loading port 30b receive wafer front opening unified pods (FOUPs) that contain wafers (e.g., semiconductor wafers or wafers made of other materials) or samples to be inspected (wafers and samples may be collectively referred to as “wafers” herein).

One or more robotic arms (not shown) in EFEM 30 may transport the wafers to load/lock chamber 20. Load/lock chamber 20 is connected to a load/lock vacuum pump system (not shown) which removes gas molecules in load/lock chamber 20 to reach a first pressure below the atmospheric pressure. After reaching the first pressure, one or more robotic arms (not shown) may transport the wafer from load/lock chamber 20 to main chamber 11. Main chamber 11 is connected to a main chamber vacuum pump system (not shown) which removes gas molecules in main chamber 11 to reach a second pressure below the first pressure. After reaching the second pressure, the wafer is subject to inspection by electron beam tool 100. Electron beam tool 100 may be a single-beam system or a multi-beam system. A controller 109 is electronically connected to electron beam tool 100, and may be electronically connected to other components as well. Controller 109 may be a computer configured to execute various controls of EBI system 10. While controller 109 is shown in FIG. 1 as being outside of the structure that includes main chamber 11, load/lock chamber 20, and EFEM 30, it is appreciated that controller 109 can be part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

A charged particle beam microscope, such as that formed by or which may be included in EBI system 10, may be capable of resolution down to, e.g., the nanometer scale, and may serve as a practical tool for inspecting IC components on wafers. With an e-beam system, electrons of a primary electron beam may be focused at probe spots on a wafer under inspection. The interactions of the primary electrons with the wafer may result in secondary particle beams being formed. The secondary particle beams may comprise backscattered electrons, secondary electrons, or Auger electrons, etc. resulting from the interactions of the primary electrons with the wafer. Characteristics of the secondary particle beams (e.g., intensity) may vary based on the properties of the internal or external structures or materials of the wafer, and thus may indicate whether the wafer includes defects.

The intensity of the secondary particle beams may be determined using a detector. The secondary particle beams may form beam spots on a surface of the detector. The detector may generate electrical signals (e.g., a current, a charge, a voltage, etc.) that represent intensity of the detected secondary particle beams. The electrical signals may be measured with measurement circuitries which may include further components (e.g., analog-to-digital converters) to obtain a distribution of the detected electrons or the electron beam intensity. The electron or beam intensity distribution data collected during a detection time window, in combination with corresponding scan path data of the primary electron beam incident on the wafer surface, may be used to reconstruct images of the wafer structures or materials under inspection. The reconstructed images may be used to reveal various features of the internal or external structures or materials of the wafer and may be used to reveal defects that may exist in the wafer.

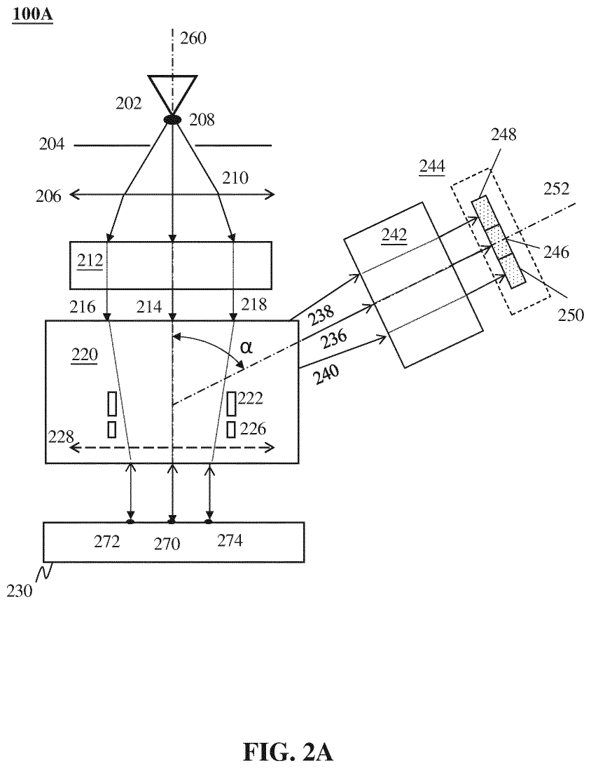

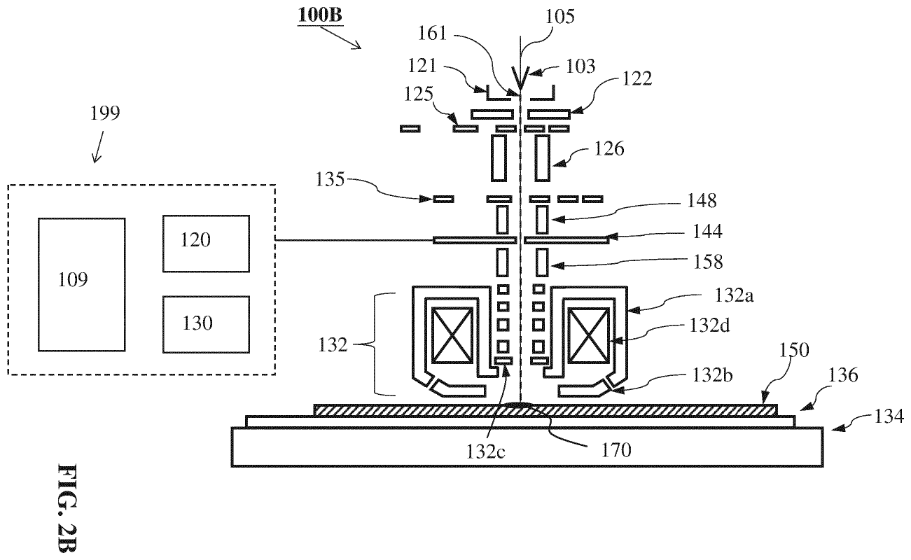

FIG. 2A illustrates a charged particle beam apparatus that may be an example of electron beam tool 100, consistent with embodiments of the present disclosure. FIG. 2A shows an apparatus that uses a plurality of beamlets formed from a primary electron beam to simultaneously scan multiple locations on a wafer.

As shown in FIG. 2A, electron beam tool 100A may comprise an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 2A), multiple secondary electron beams 236, 238, and 240, a secondary optical system 242, and electron detection device 244. Electron source 202 may generate primary particles, such as electrons of primary electron beam 210. A controller, image processing system, and the like may be coupled to electron detection device 244. Primary projection optical system 220 may comprise beam separator 222, deflection scanning unit 226, and objective lens 228. Electron detection device 244 may comprise detection sub-regions 246, 248, and 250.

Electron source 202, gun aperture 204, condenser lens 206, source conversion unit 212, beam separator 222, deflection scanning unit 226, and objective lens 228 may be aligned with a primary optical axis 260 of apparatus 100A. Secondary optical system 242 and electron detection device 244 may be aligned with a secondary optical axis 252 of apparatus 100A.

Electron source 202 may comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 may block off peripheral electrons of primary electron beam 210 to reduce size of probe spots 270, 272, and 274.

Source conversion unit 212 may comprise an array of image-forming elements (not shown in FIG. 2A) and an array of beam-limit apertures (not shown in FIG. 2A). An example of source conversion unit 212 may be found in U.S. Pat. No. 9,691,586; U.S. Publication No. 2017/0025243; and International Application No. PCT/EP2017/084429, all of which are incorporated by reference in their entireties. The array of image-forming elements may comprise an array of micro-deflectors or micro-lenses. The array of image-forming elements may form a plurality of parallel images (virtual or real) of crossover 208 with a plurality of beamlets 214, 216, and 218 of primary electron beam 210. The array of beam-limit apertures may limit the plurality of beamlets 214, 216, and 218.

Condenser lens 206 may focus primary electron beam 210. The electric currents of beamlets 214, 216, and 218 downstream of source conversion unit 212 may be varied by adjusting the focusing power of condenser lens 206 or by changing the radial sizes of the corresponding beam-limit apertures within the array of beam-limit apertures. Condenser lens 206 may be an adjustable condenser lens that may be configured so that the position of its first principle plane is movable. The adjustable condenser lens may be configured to be magnetic, which may result in off-axis beamlets 216 and 218 landing on the beamlet-limit apertures with rotation angles. The rotation angles change with the focusing power and the position of the first principal plane of the adjustable condenser lens. In some embodiments, the adjustable condenser lens may be an adjustable anti-rotation condenser lens, which involves an anti-rotation lens with a movable first principal plane. An example of an adjustable condenser lens is further described in U.S. Publication No. 2017/0025241, which is incorporated by reference in its entirety.

Objective lens 228 may focus beamlets 214, 216, and 218 onto a wafer 230 for inspection and may form a plurality of probe spots 270, 272, and 274 on the surface of wafer 230. Secondary electron beamlets 236, 238, and 240 may be formed that are emitted from wafer 230 and travel back toward beam separator 222.

Beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. Beam separator 222 may separate secondary electron beams 236, 238, and 240 from beamlets 214, 216, and 218 and direct secondary electron beams 236, 238, and 240 towards secondary optical system 242.

Deflection scanning unit 226 may deflect beamlets 214, 216, and 218 to scan probe spots 270, 272, and 274 over an area on a surface of wafer 230. In response to incidence of beamlets 214, 216, and 218 at probe spots 270, 272, and 274, secondary electron beams 236, 238, and 240 may be emitted from wafer 230. Secondary electron beams 236, 238, and 240 may comprise electrons with a distribution of energies including secondary electrons and backscattered electrons. Secondary optical system 242 may focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of the surface of wafer 230. Detection sub-regions 246, 248, and 250 may include separate detector packages, separate sensing elements, or separate regions of an array detector. In some embodiments, each detection sub-region may include a single sensing element.

Another example of a charged particle beam apparatus will now be discussed with reference to FIG. 2B. An electron beam tool 100B (also referred to herein as apparatus 100B) may be an example of electron beam tool 100 and may be similar to electron beam tool 100A shown in FIG. 2A. However, different from apparatus 100A, apparatus 100B may be a single-beam tool that uses only one primary electron beam to scan one location on the wafer at a time.

As shown in FIG. 2B, apparatus 100B includes a wafer holder 136 supported by motorized stage 134 to hold a wafer 150 to be inspected. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In a detection or imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 100B through a medium such as an electrical conductor, optical fiber cable, portable storage media, IR, Bluetooth, internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as image averaging, generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses may be used for controlling the electron beam. For example, first quadrupole lens 148 may be controlled to adjust the beam current and second quadrupole lens 158 may be controlled to adjust the beam spot size and beam shape.

FIG. 2B illustrates a charged particle beam apparatus that may use a single primary beam configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150. FIG. 2B shows an example of detector 144 having an opening at its center. However, some embodiments may use a detector placed off-axis relative to the optical axis along which the primary electron beam travels. For example, as in the embodiment shown in FIG. 2A, discussed above, a beam separator 222 may be provided to direct secondary electron beams toward a detector placed off-axis. Beam separator 222 may be configured to divert secondary electron beams by an angle α toward an electron detection device 244, as shown in FIG. 2A.

A detector in a charged particle beam system may include one or more sensing elements. The detector may comprise a single-element detector or an array with multiple sensing elements. Sensing elements may include a diode or an element similar to a diode that may convert incident energy into a measurable signal. For example, sensing elements in a detector may include a PIN diode.

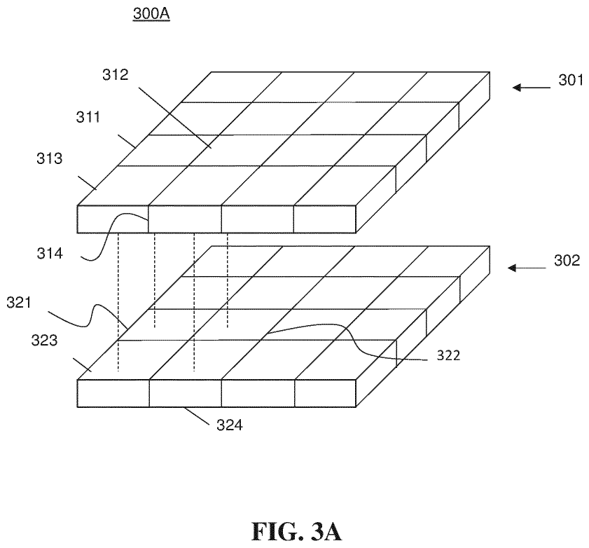

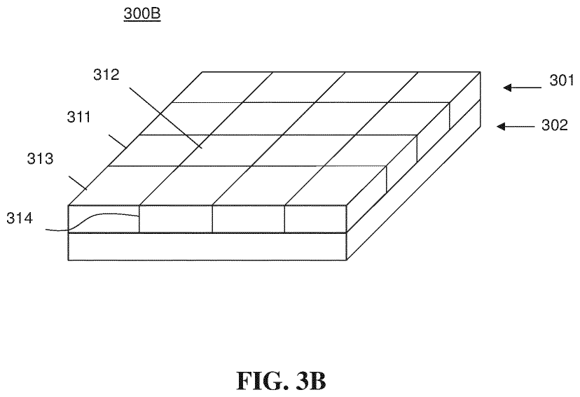

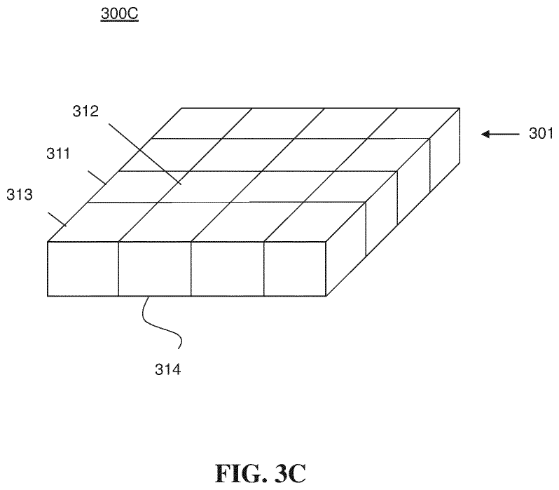

FIGS. 3A-3C illustrate exemplary structures of a detector, consistent with embodiments of the present disclosure. The detector may be a segmented detector. A detector such as detector 300A, detector 300B, or detector 300C as shown in FIGS. 3A-3C may be provided as charged-particle detection device 244 as shown in FIG. 2A or detector 144 as shown in FIG. 2B. In FIG. 3A, detector 300A includes a sensor layer 301 and a signal processing layer 302. Sensor layer 301 may include a sensor die made up of multiple sensing elements, including sensing elements 311, 312, 313, and 314. In some embodiments, the multiple sensing elements may be provided in an array of sensing elements, each of which may have a uniform size, shape, and arrangement.

Signal processing layer 302 may include multiple signal processing circuits, including circuits 321, 322, 323, and 324. The circuits may include interconnections (e.g., wiring paths) configured to communicatively couple sensing elements. Each sensing element of sensor layer 301 may have a corresponding signal processing circuit in signal processing layer 302. Sensing elements and their corresponding circuits may be configured to operate independently. As shown in FIG. 3A, circuits 321, 322, 323, and 324 may be configured to communicatively couple to outputs of sensing elements 311, 312, 313, and 314, respectively, as shown by the four dashed lines between sensor layer 301 and signal processing layer 302.

In some embodiments, signal processing layer 302 may be configured as a single die with multiple circuits provided thereon. Sensor layer 301 and signal processing layer 302 may be in direct contact. For example, as shown in FIG. 3B, which shows detector 300B, signal processing layer 302 directly abut sensor layer 301.

In some embodiments, components and functionality of different layers may be combined or omitted. For example, signal processing layer 302 may be combined with sensor layer 301. As shown in FIG. 3C, a detector 300C may be provided. Detector 300C may include sensor layer 301. Detector 300C may be configured for back-side illumination, and sensor layer 301 may be the only layer provided. A first side of sensor layer 301 may be configured to receive charged particles, and circuitry may be provided on a second side, opposite from the first side.

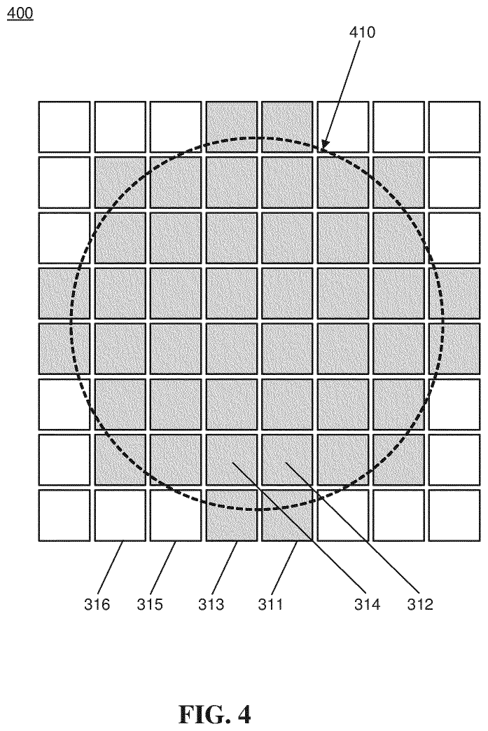

Now reference is made to FIG. 4. FIG. 4 is a diagrammatic representation of a sensor surface of a detector, consistent with embodiments of the disclosure. In some embodiments, sensor surface 400 of a detector may form a surface of charged-particle detection device 244 as shown in FIG. 2A or detector 144 as shown in FIG. 2B. In some embodiments, sensor surface 400 may be a surface of sensor layer 301 of FIGS. 3A-3C. In some embodiments, sensor surface 400 may be a surface on which incoming charged particles are incident. Sensor surface 400 may include an array of sensing elements, including sensing elements 311 to 316.

FIG. 4 shows a spot 410 on sensor surface 400. Some of sensing elements constituting sensor surface 400 may be receiving charged particles (e.g., sensing elements 311, 312, 313, and 314) while some sensing elements may not (e.g., sensing elements 315 and 316). Secondary particles may be formed in response to a primary beam of a charged particle beam apparatus being projected on a wafer, and the secondary particles may be directed to a detector. Although spot 410 is shown to have a generally round shape in FIG. 4, secondary particles may be incident on sensor surface 400 in various other patterns. While FIG. 4 illustrates 64 (8×8) sensing elements, it will be appreciated that any number of sensing elements may be used.

While FIG. 4 illustrates only one beam (i.e., spot 410) on sensor surface 400, multiple beams can simultaneously land on sensor surface 400 according to some embodiments of the present disclosure. Therefore, multiples circuits corresponding to multiple beams may be used to detect a beam intensity of each of multiple beams. For example, detector 300 may comprise 38×38 channels in a readout IC to detect beam intensities of 1444 beams.

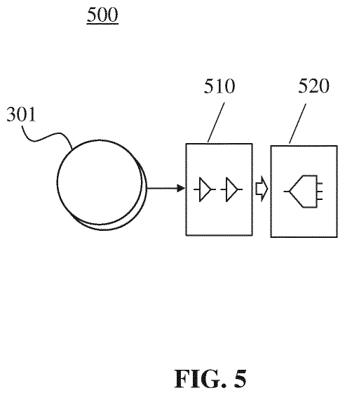

Reference is now made to FIG. 5, which shows a diagrammatic representation of a detection system architecture that may be configured for handling an analog signal from sensor layer 301. In some embodiments, a detection system 500 of FIG. 5 may represent one detection channel for detecting a beam intensity of an individual beam (e.g., forming spot 410 in FIG. 4). For example, detection system 500 may measure signals from multiple sensing elements (e.g., sensing elements 311, 312, 313, and 314) that receive charged particles forming one individual beam (e.g., spot 410 in FIG. 4). Detection system 500 may include sensor layer 301, an analog signal path 510, and an ADC 520. Analog signal path 510 may include a signal conditioning circuit that is configured to process an output from one or more sensing elements of sensor layer 301, such as a PIN diode. A signal conditioning circuit may include a current buffer and a transimpedance amplifier. Analog signal path 510 may further include a main amplifier. ADC 520 may convert an analog signal to a digital signal, detection system 500 may further comprise a digital interface that may communicate with components of EBI system 10, for example, a deflection and image control (DIC) unit via a transceiver, which may include a transmitter TX and receiver RX.

As illustrated above, inspection systems and image reconstruction processes by the inspection systems are complicated. Therefore, when system level performance issues are discovered, it is difficult to determine what in the inspection system causes the issues. For example, there can be many possible reasons in the inspection system or in the image reconstruction process that may cause one performance issue such as a sub-standard inspection image. As inspection systems get more complicated, it gets more difficult to find root causes and system down time for debugging becomes longer, and therefore efficiency of a chip manufacturing process can be degraded. Embodiments of the disclosure may provide an on-system self-diagnosis technique for a charged particle inspection system.

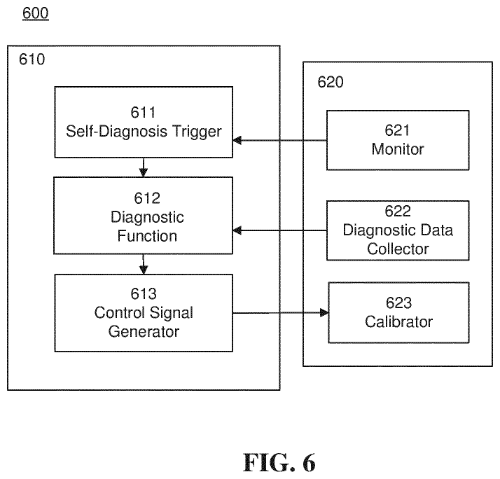

FIG. 6 is a block diagram of an example self-diagnosis and calibration system, consistent with embodiments of the present disclosure. According to some embodiments of the present disclosure, self-diagnosis and calibration system 600 may include a control apparatus 610 and a built-in apparatus 620. It is appreciated that in various embodiments, control apparatus 610 may be part of or may be separate from a charged particle beam inspection system (e.g., EBI 10 of FIG. 1). In some embodiments, control apparatus 610 may be part of, for example, controller 109 or part of other modules of FIGS. 1, 2A, and 2B. Built-in apparatus 620 can be a built-in hardware of a charged particle beam inspection system (e.g., EBI 10 of FIG. 1), or a charged particle beam apparatus (e.g., electron beam tool 100 of FIG. 1 or electron beam tool 100A or 100B of FIG. 2A or FIG. 2B). Built-in apparatus 620 may be embedded in electron beam tool 100 during manufacturing electron beam tool 100. In some embodiments, built-in apparatus 620 may include firmware that enables an operation of hardware included in built-in apparatus 620.

As illustrated in FIG. 6, control apparatus 610 may include self-diagnosis trigger 611, diagnostic function 612, and control signal generator 613. Built-in apparatus 620 may include a monitor 621, a diagnostic data collector 622, and a calibrator 623.

According to some embodiments of the present disclosure, self-diagnosis trigger 611 may acquire system level output data. System level output data may include an inspection image of a sample to be inspected or a property(s) of an inspection image. A property(s) of an inspection image may include an image distortion degree, an image sharpness degree, image grey level, or an image contrast ratio, etc. In some embodiments, self-diagnosis trigger 611 may acquire an inspection image of a sample to be inspected. In some embodiments, self-diagnosis trigger 611 may generate an inspection image based on a detection signal from electron detection device 244 or 144 of FIG. 2A or 2B. In some embodiments, self-diagnosis trigger 611 may be part of or may be separate from an image acquirer included in controller 109. In some embodiments, self-diagnosis trigger 611 may obtain an inspection image generated by an image acquirer included in controller 109. In some embodiments, self-diagnosis trigger 611 may obtain an inspection image from a storage device or system storing the inspection image. In some embodiments, self-diagnosis trigger 611 may acquire a property(s) of an inspection image. In some embodiments, self-diagnosis trigger 611 may extract a property(s) of an inspection image.

Self-diagnosis trigger 611 is configured to determine whether an inspection image or a property(s) of an inspection image meets a quality standard that may be preset for an inspection system or a sample. In some embodiments, a quality criterion of an inspection image may comprise a criterion related to an image distortion degree, an image sharpness degree, image grey level, or an image contrast ratio, etc. In some embodiments, a determination whether quality of an inspection image meets preset criteria can be performed by referring to a reference image. In some embodiments, a reference image can comprise a wafer design layout of a corresponding sample, such as in Graphic Database System (GDS) format, Graphic Database System II (GDS II) format, an Open Artwork System Interchange Standard (OASIS) format, a Caltech Intermediate Format (CIF), etc. The wafer design layout may be based on a pattern layout for constructing the wafer. In some embodiments, a reference image, among others, may comprise feature information stored in a binary file format representing planar geometric shapes, text, and other information related to wafer design layout. The wafer design layout may correspond to one or more photolithography masks or reticles used to transfer features from the photolithography masks or reticles to a wafer.

A determination of self-diagnosis trigger 611 that an inspection image or inspection image property(s) is sub-standard may trigger a self-diagnosis process, consistent with some embodiments of the present disclosure. In some embodiments, after self-diagnosis trigger 611 determines that an inspection image or an inspection image property(s) is sub-standard, diagnostic function 612 can be notified to enable the initiation of a self-diagnosis process.

In some embodiments, self-diagnosis trigger 611 may acquire sub-system level output data of a sub-system associated with built-in apparatus 620. Sub-system level output data may comprise output data of a sub-system or performance information of the output data of the sub-system. In some embodiments, self-diagnosis trigger 611 may acquire sub-system level output data, for example, from monitor 621 that is configured to collect output data of a sub-system or of each function block of the sub-system. In some embodiments, monitor 621 may be configured to collect real-time information of an operation status of a corresponding sub-system or a function block during a normal operation of an inspection system. In some embodiments, sub-system level output data may continuously be collected by monitor 621 in real time during operation of an inspection system. Thereby, self-diagnosis trigger 611 may track output of a sub-system and evaluate performance of the sub-system of an inspection system. In some embodiments, by monitoring continuously accumulated data of a sub-system or a function block, it may be possible to predict a performance trend of a system, a sub-system, or a function block and thus to predict a possible failure, a possible diagnostic issue, a possible maintenance need, etc. for a system, a sub-system, or a function block. In some embodiments, performance evaluation or prediction may be performed by means of a machine learning technology. In some embodiments, performance information of a sub-system or a function block may comprise information about possible failure, possible diagnostic issue, a possible maintenance need, etc. In some embodiments, self-diagnosis trigger 611 may receive performance information of a sub-system based on output data of the sub-system from another function module. In some embodiments, self-diagnosis trigger 611 may acquire sub-system level output data from a detection channel (e.g., detection system 500 of FIG. 5), each function block (e.g., sensor layer 301, analog signal path 510, or ADC 520 of FIG. 5) of a detection channel.

In some embodiments, self-diagnosis trigger 611 may acquire diagnosis history data (e.g., from diagnostic function 612) for a whole system, a sub-system, or a function block. In some embodiments, tracking diagnosis history data along with data from each sub-system or a function block may help in improving accuracy of performance evaluation, diagnostic issue prediction, failure prediction, related maintenance plan prediction, etc. In some embodiments, self-diagnosis trigger 611 may also acquire maintenance history data (e.g., from control signal generator 613), maintenance schedule data, etc. for a whole system, a sub-system, or a function block. In some embodiments, tracking maintenance history data or maintenance schedule data may help in improving accuracy of maintenance timing prediction, maintenance component prediction, etc. In some embodiments, when evaluating or predicting performance of a system at issue, data accumulated from other systems can be used to improve performance evaluation or prediction accuracy. In some embodiments, because each system may encounter different issues during its operation, performance evaluation or prediction accuracy of one system can be improved by considering data from multiple systems. In some embodiments, data from other systems can also be collected as illustrated in the present disclosure.

In some embodiments, self-diagnosis trigger 611 may be configured to determine whether sub-system level output data or performance information of the sub-system level output data meets an operation criterion. In some embodiments, an operation criterion may be a normal operation range of output data for a sub-system. According to some embodiments of the present disclosure, an operation criterion can be set based on previous operation records of the inspection system including the sub-system at issue, operation records of other similar inspection systems, parameter setting, etc. In some embodiments, when performance information of a sub-system or a function block indicates that there is possible failure, possible diagnostic issue, a possible maintenance need, etc. self-diagnosis trigger 611 may determine that the performance information does not meet an operation criterion. In some embodiments, a determination of self-diagnosis trigger 611 that sub-system level output data or performance information of the sub-system level output data does not meet an operation criterion may trigger a self-diagnosis process. According to some embodiments, by monitoring performance or sub-system level output data, prediction of failures or malfunctions at function block level, sub-system level, or even system level may be possible and thus maintenance can be planned in advance of the malfunction. Thereby, a maintenance cost including maintenance time can be greatly reduced and thus overall performance of an inspection system can be improved.

In some embodiments, self-diagnosis trigger 611 is configured to monitor system level output data and sub-system level output data together. By monitoring the system level output data and sub-system level output data together, self-diagnosis trigger 611 may evaluate which sub-system does not operate in a normal operation range when an inspection image or inspection image property(s) is determined to be sub-standard. In some embodiments, a self-diagnosis process may be performed with respect to a sub-system(s) that does not meet an operation criterion. According to some embodiments, by monitoring system level output data and sub-system level output data from each function block within a sub-system together, an operation status of a sub-system can be better tracked, and performance of the sub-system can be properly maintained by calibrations or adjustments according to the tracking results. Further, tracking system level output data and sub-system level output data together may reduce search space for finding a root cause of system level issues such as image degradation, and thereby debugging can be performed in a shorter amount of time. Therefore, overall up time of an inspection system can be improved.

In some embodiments, self-diagnosis trigger 611 can be implemented as a machine learning or deep learning network model. In some embodiments, a machine learning model can predict whether an input inspection image or a property(s) of an inspection image is sub-standard or not. According to some embodiments of the present disclosure, a machine learning model can be pre-trained with training inspection images, e.g., acquired by an inspection system. In some embodiments, a machine learning model can be pre-trained under supervised learning, semi-supervised learning, or unsupervised learning. In some embodiments, a machine learning model can be pre-trained with a reference image corresponding to a training inspection image. Similarly, in some embodiments, a machine learning model can predict whether a sub-system operates properly based on sub-system level output data, diagnosis history data, maintenance history data, or maintenance schedule data of the sub-system, or data accumulated from other systems, etc. In some embodiments, machine learning model can be trained with sub-system level output data, diagnosis history data, maintenance history data, or maintenance schedule data of the sub-system, or data accumulated from other systems, etc. to accurately predict a possible failure, a possible diagnostic issue, a possible maintenance need, or performance of a system, a sub-system, or a function block. In some embodiments, a machine learning model can predict whether a sub-system operates properly by considering data from a function block(s) of the sub-system as well as data from the sub-system itself. Thereby, the machine learning model can accurately predict a possible issue(s) of the sub-system even when performance information of each function block of the sub-system indicates that the corresponding function block operates properly. In some embodiments, a machine learning model may be trained with human's assistants (e.g., human inputs) to accurately predict a sub-system or function block to be diagnosed, calibrated, tuned, replaced, etc.

According to some embodiments, after a self-diagnosis process is triggered by self-diagnosis trigger 611, diagnostic function 612 can initiate a self-diagnosis process. In some embodiments, diagnostic function 612 is configured to diagnose sub-components or sub-systems of inspection system 10 to determine what causes a defect of an inspection image, such as a sub-standard quality image. In some embodiments, diagnostic function 612 may determine which sub-system does not properly operate. According to some embodiments of the present disclosure, diagnostic function 612 may perform a diagnosis based on data collected by diagnostic data collector 622. In some embodiments, diagnostic data collector 622 may start collecting data once a corresponding instruction is received from diagnostic function 612.

As discussed above, diagnostic data collector 622 included in built-in apparatus 620 is embedded in an inspection system or electron beam tool associated with one or more components or sub-systems of an inspection system. In some embodiments, diagnostic data collector 622 may be configured to generate a test signal for checking a performance of a corresponding sub-system or a function block and to receive an output signal from the sub-system or the function block in response to the injected test signal. According to some embodiments of the present disclosure, diagnostic data collector 622 can be implemented as hardware. In some embodiments, diagnostic data collector 622 may comprise circuitry to generate a test signal and to receive an output signal from the sub-system or function block generated in response to the test signal. Circuitry included in diagnostic data collector 622 may comprise a signal source (e.g., current source or voltage source) that generates a test signal and that injects (e.g., transmits) the test signal to an associated sub-system. In some embodiments, an output signal from the associated component can be targeted data for diagnosis.

Diagnostic function 612 can perform a diagnosis based on data collected from diagnostic data collector 622. If the diagnosis by diagnostic function 612 shows that a sub-system or a function block associated with the collected data operates properly in view of a preset standard, diagnostic function 612 may determine that the sub-system (or function block) does not cause a performance issue. In some embodiments, diagnostic function 612 may perform the diagnosis for other sub-systems. If the diagnosis by diagnostic function 612 shows that a sub-system or a function block associated with the collected data operates improperly in view of a preset standard, diagnostic function 612 may determine that the sub-system (or function block) is a root cause for a performance issue. While FIG. 6 illustrates one built-in apparatus 620, it will be appreciated that multiple built-in apparatuses 620 may be used associated with its own sub-system or a function block. Multiple built-in apparatuses 620 may operate simultaneously or sequentially according to embodiments of the present disclosure.

According to some embodiments, when it is determined that a certain sub-system or function block does not operate properly or is a root cause for a performance issue, control signal generator 613 may be configured to generate a control signal to perform a calibration to a sub-system or a function block based on a diagnosis result. In some embodiments, a control signal generated from control signal generator 613 may be transmitted to an associated sub-system or function block to adjust operation parameters of the sub-system or function block according to the control signal. In some embodiments, calibrator 623 included in built-in apparatus 620 may be configured to adjust parameters according to the control signal.

According to some embodiments of the present disclosure, diagnostic data collector 622 may collect diagnostic data including, but not limited to, primary beam fluctuation or profile information, beam aberration information, beam-limit aperture performance information, or detection channel performance information. In some embodiments, data collector 622 may be configured to collect primary beam fluctuation or profile information. Fluctuation of a primary beam can be a change of an amount of a primary beam current over time. A change of an amount of a primary beam current that lands on a sample may cause a grey level change of a reconstructed image therefrom. A profile of a primary beam can be a size, shape, etc. of a primary beam spot of a sample. A profile of a primary beam spot may affect overall system performance. For example, when a profile of a primary beam spot is different from an intended profile, overall image quality may be degraded. In some embodiments, information regarding a primary beam profile may be obtained by using a sample having one or more known fine features thereon. In some embodiments, the primary beam profile may be derived from an SEM image of the sample having the known fine features.

In some embodiments, diagnostic data collector 622 may be installed to collect primary beam profile or fluctuation information from a detection channel. Diagnostic data collector 622 may be configured to collect a SEM image(s) that is taken from a sample(s) having one or more known features thereon to determine a primary beam profile(s).

When diagnostic function 612 determines that a primary beam unintendedly fluctuates over time, control signal generator 613 can generate a control signal to correct primary beam fluctuation. In some embodiments, the control signal may be used to calibrate or adjust operation parameters of electron source 202 such that electron source 202 generates a more constant amount of primary particles over time. In some embodiments, the control signal may be transmitted to controller 109 such that controller 109 adjusts an operation of electron source 202 to generate a more constant amount of primary particles over time. Similarly, when diagnostic function 612 determines that a primary beam profile is different from an intended profile, control signal generator 613 can generate a control signal to correct a primary beam profile. In some embodiments, the control signal may be used to adjust an operation of image-forming elements (e.g., included in source conversion unit 212 in FIG. 2A) or lenses (e.g., quadrupole lens 148 or 158 in FIG. 2B) of electron beam tool 100A or 100B such that a primary beam profile is properly adjusted. In some embodiments, the control signal may be transmitted to controller 109 such that controller 109 adjusts an operation of image-forming elements or lenses, etc. of electron beam tool 110A or 100B to properly adjust a primary beam profile.

In some embodiments, data collector 622 may be configured to collect beam aberration information. Beam aberration may occur when lenses do not properly focus a primary beam or a secondary beam. In some embodiments, beam aberration information may be obtained by measuring a location, size, or shape of a beam spot (e.g., spot 410 of FIG. 4), which is similar to beam fluctuation or profile information. In some embodiments, diagnostic data collector 622 may be installed to collect beam aberration information from a detection channel. When diagnostic function 612 determines that a beam aberration occurs, control signal generator 613 can generate a control signal to correct a beam aberration. In some embodiments, the control signal may be used to adjust lenses (e.g., objective lens 228 in FIG. 2A or objective lens assembly 132 or control electrode 132b in FIG. 2B) of electron beam tool 100A or 100B such that a primary beam is properly focused on a sample. In some embodiments, the control signal may be used to adjust secondary optical system (e.g., secondary optical system 242 in FIG. 2A) such that a secondary beam is properly focused on a detector. In some embodiments, the control signal may be transmitted to controller 109 such that controller 109 adjusts an operation of lenses, etc. of electron beam tool 110A or 100B to properly focus a primary beam on a sample or to properly focus a secondary beam.

In some embodiments, data collector 622 may be configured to collect beam-limit aperture performance information. Performance information of a beam-limit aperture (e.g., beam limit aperture 125 of FIG. 2B) may comprise information regarding a beam current of each beamlet (e.g., beamlet 214, 216, and 218) formed by the beam limit aperture. In some embodiments, beam-limit aperture performance information may be obtained by measuring a beam current(s) of primary beam(s). In some embodiments, diagnostic data collector 622 may be installed to collect beam-limit aperture performance information and may include Faraday cup mounted on a stage (e.g., stage 134 in FIG. 2B) for measuring a beam current(s) of a primary beam(s). When diagnostic function 612 determines that beam-limit aperture performance is different from a preset standard, control signal generator 613 can generate a control signal to adjust beam-limit aperture performance. In some embodiments, the control signal may be transmitted to controller 109 such that controller 109 adjusts operation parameters of a beam-limit aperture.

According to some embodiments of the present disclosure, diagnostic data collector 622 may collect detection channel performance information. Detection channel performance information can be associated with detection channel health, such as offset information or bandwidth information of the detection channel, performance information of an analog signal path, performance information of a converter included in the detection channel, or noise information of the detection channel.

Offset information can be information whether a sensor layer (e.g., 301 in FIG. 5) generates a dark current or whether a detection channel (e.g., detection system 500) compensates an offset that may occur due to the dark current. In some embodiments, a diode in a sensing element may generate a current (i.e., a dark current) even when the sensing element does not receive charged particles, which leads to wrong interpretation of signals from a sensor layer. In some embodiments, diagnostic data collector 622 may measure an output signal of analog signal path 510 when charged particles are not incident on a sensing layer. When diagnostic function 612 determines that a dark current or an offset therefrom is not compensated based on the collected data, control signal generator 613 can generate a control signal to compensate the dark current or the offset. In some embodiments, a control signal from control signal generator 613 may be provided to a component in a detection channel that is designed to generate a compensation current to offset a dark current. In some embodiments, calibrator 621 may comprise a circuitry to generate a compensation current to analog signal path 510 to offset the dark current from sensing elements, and a control signal can be provided to calibrator 621.

Analog signal path performance information may comprise, but is not limited to, operation point information, linearity information, gain information, bandwidth information, overshoot or undershoot information, or offset information of analog signal path 510. Operation point information can be information of bias voltages or bias currents of analog signal path 510. For example, an operation point may be a bias voltage or bias current of an amplifier (e.g., transimpedance amplifier or main amplifier) included in analog signal path 510. An operation point of analog signal path 510 may affect overall linearity, gain, or bandwidth of a detection channel. In some embodiments, diagnostic data collector 622 may measure a bias voltage or bias current from analog signal path 510. When problem diagnostic function 612 determines that an operation point of analog signal path 510 is not within a normal operation range, control signal generator 613 can generate a control signal to adjust an operation point of analog signal path 510. In some embodiments, a control signal from control signal generator 613 may be provided to a component in detection system 500 that is designed to control an operation point such as a bias voltage or bias current. In some embodiments, calibrator 621 may comprise circuitry to control an operation point, and a control signal can be provided to calibrator 621.

Similarly, diagnostic data collector 622 may collect linearity information, gain information, bandwidth information, overshoot or undershoot information, or offset information of analog signal path 510, etc. In some embodiments, diagnostic data collector 622 may include circuitry that generates a test signal and that injects the test signal to an input terminal of analog signal path 510. The circuitry may measure an output signal from analog signal path 510 in response to the injected test signal. Diagnostic function 612 may determine whether linearity, gain, bandwidth, offset, overshoot, or undershoot of analog signal path 510 is within a normal operation range. When diagnostic function 612 determines that linearity, gain, bandwidth, offset, overshoot, or undershoot of analog signal path 510 is not within a normal operation range, control signal generator 613 can generate a control signal to adjust linearity, gain, bandwidth, offset, overshoot, or undershoot of analog signal path 510. In some embodiments, a control signal from control signal generator 613 may be provided to a component in detection system 500 such that the component can adjust or calibrate linearity, gain, bandwidth, offset, overshoot, or undershoot. In some embodiments, calibrator 623 may comprise circuitry to control linearity, gain, bandwidth, offset, overshoot, or undershoot and a control signal can be provided to calibrator 623.

ADC performance information may comprise offset information, linearity information, gain information, or bandwidth information of ADC 520. In some embodiments, diagnostic data collector 622 may include circuitry that generates a test signal and that injects the test signal to an input terminal of ADC 520. The circuitry may measure an output signal from ADC 520 in response to the injected test signal. Diagnostic function 612 may determine whether offset, linearity, gain, or bandwidth of ADC 520 is within a normal operation range. When diagnostic function 612 determines that offset, linearity, gain, or bandwidth of ADC 520 is not within a normal operation range, control signal generator 613 can generate a control signal to adjust offset, linearity, gain, or bandwidth of ADC 520. In some embodiments, a control signal from control signal generator 613 may be provided to a component in detection system 500 such that the components can adjust or calibrate offset, linearity, gain, or bandwidth. In some embodiments, calibrator 623 may comprise circuitry to control offset, linearity, gain, or bandwidth of ADC 520 and a control signal can be provided to calibrator 623.

Electronic noise information of detection system 500 can be collected. In some embodiments, diagnostic data collector 622 may collect information that indicates an electronic noise level from detection system 500. Circuitry included in diagnostic data collector 622 may measure an output signal from ADC 520 to determine an electronic noise level. Diagnostic function 612 may determine whether an electronic noise level of detection system 500 is within a normal operation range. When diagnostic function 612 determines that an electronic noise level of detection system 500 is not within a normal operation range, control signal generator 613 can generate a control signal to adjust an electronic noise level of detection system 500. In some embodiments, a control signal from control signal generator 613 may be provided to a component in detection system 500 that is designed to reduce an electronic noise level of detection system 500. In some embodiments, calibrator 623 may comprise circuitry to reduce an electronic noise level of detection system 500 and a control signal can be provided to calibrator 623.

According to some embodiments of the present disclosure, built-in apparatus 620 may further collect overall bandwidth information of detection system 500. An overall bandwidth in the present disclosure may refer to a bandwidth of a detection channel from sensor layer 301 to ADC 520 including sensor layer 301. In some embodiments, diagnostic data collector 622 may collect information that may show an overall bandwidth of detection system 500. When diagnostic function 612 determines that an overall bandwidth of detection system 500 is not within a normal operation range, control signal generator 613 can generate a control signal to adjust an overall bandwidth of detection system 500. In some embodiments, a control signal from control signal generator 613 may be provided to a component in detection system 500 such that the component can adjust or calibrate an overall bandwidth of detection system 500. In some embodiments, calibrator 623 may comprise circuitry to control an overall bandwidth of detection system 500 and a control signal can be provided to calibrator 623. In some embodiments, parameter values of detection system 500 may be adjusted according to the control signal. According to some embodiments, a detection channel bandwidth diagnosis and calibration process can be performed after a self-diagnosis and calibration process for each function block (e.g., analog signal path 510, ADC 520, etc. of FIG. 5) included in a detection channel (e.g., detection system 500) is performed. Because a detection channel is a complex sub-system that consists of multiple function blocks, optimizing an overall performance of a detection channel (e.g., bandwidth optimization) can be compute intensive and complicated. In some embodiments, a machine learning or deep learning network model can be employed to optimize an overall performance (e.g., bandwidth optimization) of a detection channel. In some embodiments, a machine learning or deep learning network model used in optimizing an overall performance of a detection channel may be implemented with human's assistants (e.g., human inputs) during training.

In an inspection system (e.g., a SEM), the detection channel bandwidth may have an effect on SEM image sharpness, and therefore overall performance and overall throughput of the SEM system can be affected by the detection channel bandwidth. A detection channel bandwidth may be affected by one or more components in a detection channel including, but not limited to, a response speed of a sensor layer (e.g., sensor layer 301 of FIG. 5), a bandwidth of an analog signal path (e.g., analog signal path of FIG. 5), or a bandwidth of a data converter (e.g., ADC 520). However, due to complexity of a detection channel, it is difficult to have accurate bandwidth measurements of a detection channel without building a dedicated test setup that may simulate operation environments of the detection channel.

Once a detection channel is incorporated into an inspection system, it is challenging to even build a dedicated test setup for estimating an overall bandwidth of the detection channel. Thereby, bandwidth estimation techniques that do not use a dedicated test setup have been introduced, however, such techniques have not been able to provide accurate bandwidth estimation. For example, a qualitative bandwidth estimation technique that is based on sharpness differences between SEM images of different delta average settings may only roughly tell whether a bandwidth of a detection channel is good enough for a certain pixel rate without providing bandwidth estimation. Because the qualitative bandwidth estimation technique heavily relies on experiences of a person who conducts the estimation, the estimation result may be subjective and inconsistent. A quantitative bandwidth estimation technique that is based on noise autocorrelation of SEM images of different delta average settings also fails to provide an estimated bandwidth value. Further, the technique based on the autocorrelation may draw a wrong conclusion because there are more than one noise source in a detection channel; not all noises in a detection channel pass a whole signal path of the detection channel; or typically noises in a detection channel are not white noises. Because estimating an accurate bandwidth of a detection channel plays an important role in detection channel performance evaluation or inspection system performance evaluation, improvements in estimating a bandwidth of a detection channel is desired. According to some embodiments of the present disclosure, accurate bandwidth estimation techniques can be provided.

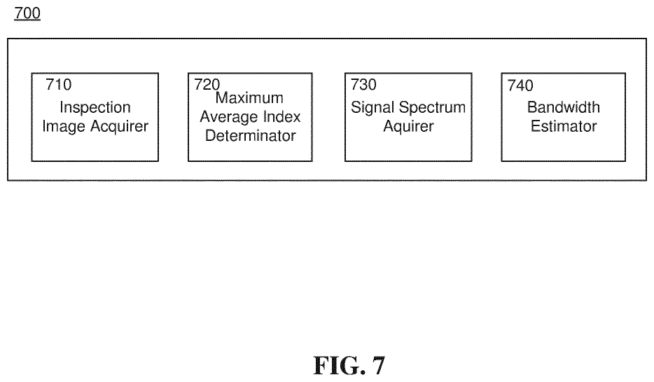

Details on how to determine an overall bandwidth of detection system 500 will be discussed referring to FIG. 7, which illustrates a block diagram of an example bandwidth estimation apparatus, consistent with embodiments of the present disclosure. It is appreciated that in various embodiments bandwidth estimation apparatus 700 may be implemented as part of diagnostic function 612. As shown in FIG. 7, bandwidth estimation apparatus 700 may include an inspection image acquirer 710, maximum average index determinator 720, signal spectrum acquirer 730, and bandwidth estimator 740.

Inspection image acquirer 710 is configured to acquire multiple inspection images of a sample. In some embodiments, inspection image acquirer 710 may generate an inspection image based on a detection signal from electron detection device 244 or 144 of electron beam tool 100. In some embodiments, inspection image acquirer 710 may be part of or may be separate from an image acquirer included in controller 109. In some embodiments, inspection image acquirer 710 may obtain an inspection image generated by an image acquirer included in controller 109. In some embodiments, inspection image acquirer 710 may obtain an inspection image from a storage device or system storing the inspection image.

In some embodiments, an inspection system may be set to operate under a preset condition(s) when obtaining an inspection image(s) to be used in estimating a detection channel bandwidth. In some embodiments, the preset condition may comprise: (1) an inspection system maintains a normal operation state without any operation issue, (2) a primary electron beam is properly focused on a sample surface, (3) a spot size of a primary electron beam on a sample surface is tuned to be at most ⅕ size of the smallest feature on the sample, or (4) a spot shape of a primary electron beam is tuned to have a round shape, e.g., by fine-tuning a stigmator of an inspection system. In order to improve bandwidth estimation accuracy, a sample having one or more sharp edges such as a line pattern or a grid pattern may be used to obtain multiple inspection images. When a line pattern is used in a sample, a line scanning direction to obtain multiple inspection images may be set to be perpendicular to a length direction of a line to improve bandwidth estimation accuracy. In some embodiments, also to improve bandwidth estimation accuracy, an acquired inspection image is an image reconstructed by output signals that do not have clippings on lower bound or higher bound by a limit of a detection channel. Clipping is a form of distortion that limits a signal when it exceeds a threshold of a circuit and may produce a flat cutoff or may follow the original signal at a reduced gain.

In some embodiments, multiple inspection images may be obtained by an inspection system by using different average settings. When no average scheme is used, a primary beam spot (e.g., probe spot 270, 272, or 274 of FIG. 2A or probe spot 170 of FIG. 2B) may not stay at each location on a sample that corresponds to a pixel in an inspection image (as the beam scans from one side of the pixel to the other) and move pixel by pixel and line by line until a whole frame is scanned. In this case, a signal of each pixel may be obtained by measuring a signal generated during one pixel period. There are various average schemes such as a dot average, a line average, a frame average, etc. For example, an average setting xDyLzF represent x time dot average, y time line average, and z time frame average. Under x time dot average setting, a primary beam spot may stay on each location on a sample that corresponds to a pixel in an inspection image for x times of one pixel period and a signal of each pixel may be obtained by averaging a signal measured during the x times of one pixel period. Similarly, under y time line average setting, a primary beam may scan each line of a sample y times and a signal of each pixel may be obtained by averaging y number of signals corresponding to the pixel obtained during y times of line scanning. Under z time frame average, a primary beam may scan each frame corresponding to a field of view (FOV) on a sample z times and a signal of each pixel may be obtained by averaging z times of signals corresponding to the pixel obtained during z times of frame scanning. While any combination of average schemes may be used according to some embodiments of the present disclosure, it will be appreciated that a dot average scheme is used in the present disclosure for illustration purposes.

According to some embodiments of the present disclosure, multiple inspection images of a same sample may be obtained by using different average settings. In some embodiments, multiple inspection images can be taken for a same pattern at a same location of a sample. For example, n number of inspection images may be obtained by using n different average settings. A first inspection image may be obtained without using an average scheme (e.g., represented as 1D1L1F) of which average index is defined as 1, a second inspection image may be obtained by using 2 time dot average (e.g., 2D1L1F) of which average index is defined as 2, and a n^{th} inspection image may be obtained by using n time dot average (e.g., nD1L1F) of which average index is defined as n. In some embodiments, a pixel size may be selected such that each pixel has enough exposure time while maintaining a proper scanning speed to preserve higher frequency components in a first inspection image obtained with average index 1 (e.g., 1D1L1F). Thereby, sharpness differences between multiple inspection images may become clearer.

Maximum average index determinator 720 is configured to determine a highest average index from which increase of an average index does not improve inspection image sharpness or from which increase of an average index does not reduce inspection image blurriness. Maximum average index determinator 720 may analyze whether there is sharpness improvement or blurriness reduction between a first inspection image and a second inspection image. If there is sharpness improvement, maximum average index determinator 720 may continue to analyze whether there is sharpness improvement between a second inspection image and a third inspection image. If there is sharpness improvement, maximum average index determinator 720 may continue to perform the analysis with respect to subsequent inspection images until there is no further sharpness improvement between two adjacent inspection images. For example, if maximum average index determinator 720 determines that there is no sharpness improvement between a n−1^{th} inspection image and a n^{th} inspection image while there is sharpness improvement between a n−2^{th} inspection image and a n−1^{th} inspection image, the number n can be determined as a maximum average index. In some embodiments, a predetermined criterion or threshold can be used when determining whether there is sharpness improvement. If a degree of sharpness improvement is below the criterion or threshold, it can be determined that there is no sharpness improvement. If a degree of sharpness improvement is equal to or greater than the criterion or the threshold, it can be determined that there is sharpness improvement.

Signal spectrum acquirer 730 is configured to acquire signal spectrums corresponding to a first inspection image obtained with average index 1 and a n^{th} inspection image obtained with maximum average index n (e.g., nD1L1F). In some embodiments, a first time-domain signal can be acquired from a first inspection image obtained with average index 1. Similarly, a n^{th} time-domain signal can be acquired from a n^{th} inspection image obtained with maximum average index n. In some embodiments, a first time-domain signal can also be acquired from an output signal of ADC 520 in that no average scheme is used when obtaining a first inspection image. According to some embodiments, a first time-domain signal and a n^{th} time-domain signal can be acquired by diagnostic data collector 622 and transmitted to signal spectrum acquirer 730.

According to some embodiments, signal spectrum acquirer 730 may obtain a signal spectrum for each of a first time-domain signal and a n^{th} time-domain signal. In some embodiments, signal spectrum acquirer 730 may obtain a signal spectrum for a time-domain signal by a Fourier transform. Signal spectrum acquirer 730 may acquire a first signal spectrum S₁(f) corresponding to a first time-domain signal and a n^{th} signal spectrum Sₙ(f) corresponding to a n^{th} time-domain signal.

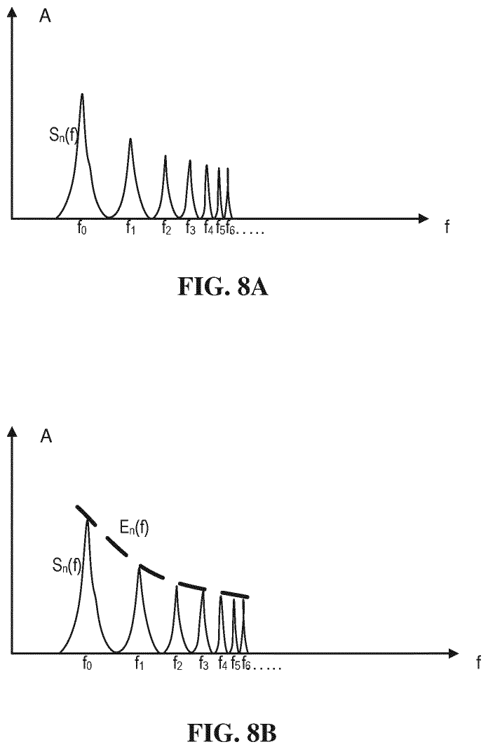

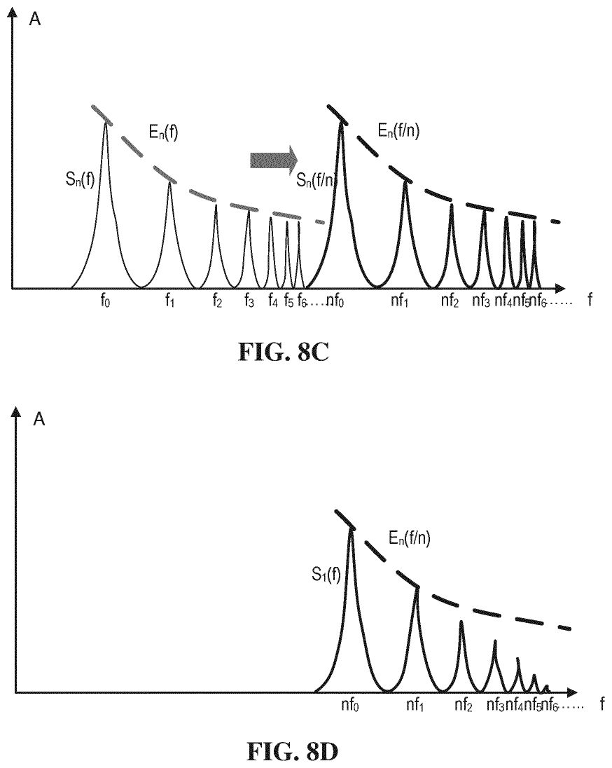

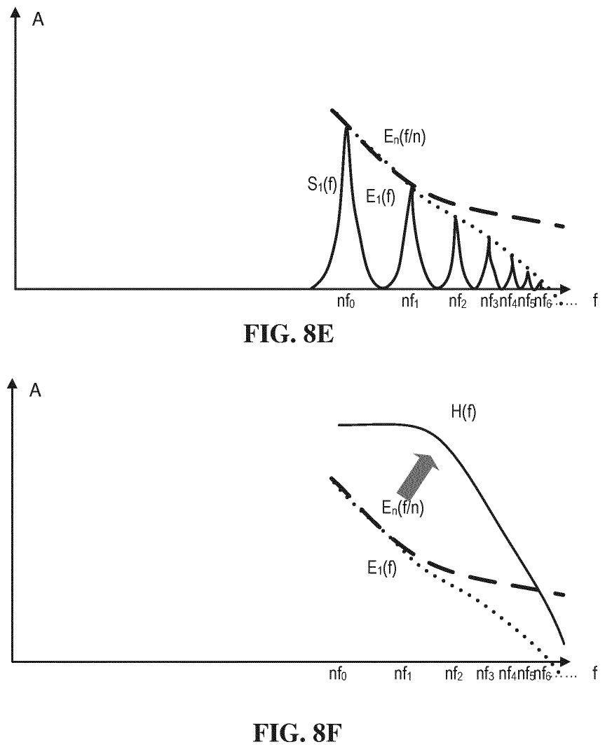

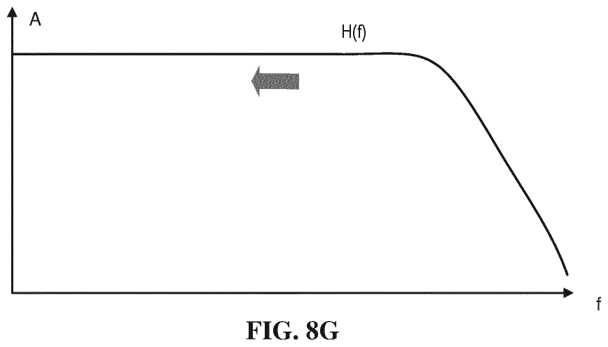

Bandwidth estimator 740 is configured to estimate a bandwidth of a detection channel based on a first signal spectrum S₁(f) and an n^{th} signal spectrum Sₙ(f). A process of estimating a bandwidth will be explained by referring to FIGS. 8A-8G as an example. In FIGS. 8A-8G, graphs are represented in a log-log scale. FIG. 8A shows an example n^{th} signal spectrum Sₙ(f) in which a horizontal axis represents a frequency of a signal and a vertical axis represents an amplitude of a signal. FIG. 8A shows that an n^{th} signal spectrum Sₙ(f) include various frequency components, e.g., including f₀, f₁, f₂, f₃, f₄, f₅, f₆, etc.

Bandwidth estimator 740 may acquire an n^{th} spectral envelope function Eₙ(f) of an n^{th} signal spectrum Sₙ(f) as shown in FIG. 8B. In some embodiments, an n^{th} spectral envelope function Eₙ(f) of an n^{th} signal spectrum Sₙ(f) can be obtained by curve fitting.

As shown in FIG. 8C, a shifted n^{th} spectral envelope function Eₙ(f/n) of an n^{th} spectral envelope function Eₙ(f) can be obtained. A shift ratio (i.e., n) can be determined by the determined maximum average index, i.e., n. By shifting an n^{th} spectral envelope function Eₙ(f) by a ratio of a maximum average ratio to average index 1, a reference spectral envelope function Eₙ(f/n) that is within a same high frequency range as a first signal spectrum S₁(f) can be obtained, which is shown in FIG. 8D. As shown in FIG. 8D, while a first signal spectrum S₁(f) is distributed in a same frequency range as a shifted n^{th} spectral envelope function Eₙ(f/n) corresponding to a shifted n^{th} signal spectrum Sₙ(f/n), a first signal spectrum S₁(f) has a different shape from that of a shifted n^{th} signal spectrum Sₙ(f/n). One reason for a shape difference between a first signal spectrum S₁(f) and an n^{th} signal spectrum Sₙ(f) may be that, in a first signal spectrum S₁(f), some frequency components, e.g., higher frequency components have amplitude reduction due to a bandwidth limitation of a detection channel while, in an n^{th} signal spectrum Sₙ(f), those frequency components do not have any amplitude reduction. In the present disclosure, an n^{th} signal spectrum Sₙ(f) corresponds to an n^{th} inspection image obtained with a maximum average index from which increase of an average ratio does not improve sharpness or from which increase of an average ratio does not reduce blurriness, which may mean that an equivalent bandwidth of a detection channel has no impact on acquisition of an n^{th} signal spectrum Sₙ(f). For example, as shown in FIG. 8D, in a first signal spectrum S₁(f), some frequency components higher than frequency nf₁ have amplitude reduction while frequency components lower or equal to frequency nf₁ do not have any amplitude reduction.

Bandwidth estimator 740 may acquire a first spectral envelope function E₁(f) of a first signal spectrum S₁(f) as shown in FIG. 8E. In some embodiments, a first spectral envelope function E₁(f) of a first signal spectrum S₁(f) can be obtained by curve fitting.

Bandwidth estimator 740 may acquire a frequency response of a detection channel based on a first spectral envelope function E₁(f) and a reference function, i.e., a shifted n^{th} spectral envelope function Eₙ(f/n). As discussed above, a shifted n^{th} signal spectrum Sₙ(f/n) corresponds to an output signal of a detection channel without impacts from a limited detection channel bandwidth and a first signal spectrum S₁(f) corresponds to an output signal of a detection channel that has been affected by a bandwidth limitation of the detection channel; and a shifted n^{th} signal spectrum Sₙ(f/n) and a first signal spectrum S₁(f) are spread in the same high frequency range. Therefore, a first signal spectrum S₁(f) can be interpreted as a spectrum of a response signal of a detection channel to an equivalent input signal of which spectrum is a shifted n^{th} signal spectrum Sₙ(f/n).

In some embodiments, bandwidth estimator 740 may acquire a partial frequency response of a detection channel in a partial frequency range where a first signal spectrum S₁(f) lies. In some embodiments, an estimated frequency response H(f) of a detection channel in a partial frequency range can be obtained by a ratio between a first spectral envelope function E₁(f) and a reference function, i.e., a shifted n^{th} spectral envelope function Eₙ(f/n). An estimated frequency response H(f) of a detection channel in a partial frequency range can be represented as H(f)=E₁(f)/Eₙ(f/n).

As shown in FIG. 8F, an estimated frequency response H(f) obtained by a ratio between a first spectral envelope function E₁(f) and reference function Eₙ(f/n) has roll-off in the partial frequency range. When comparing a first spectral envelope function E₁(f) and reference function Eₙ(f/n), a first spectral envelope function E₁(f) has almost no amplitude reduction in a frequency range lower or equal to frequency nf₀. Therefore, an estimated frequency response H(f) has a constant response (i.e., flat portion) in a frequency range from the point that a first spectral envelope function E₁(f) starts to frequency nf₀, and roll-off starts approximately after frequency nf₀. It is appreciated that a frequency response of a detection channel is assumed to have a low-pass filter profile in a frequency domain in the present disclosure. Therefore, in some embodiments of the present disclosure, an entire estimated frequency response H(f) can be obtained by extending the constant response portion of partial frequency response H(f) for a lower frequency range, i.e., from frequency 0 to the point that a first spectral envelope function E₁(f) starts as shown in FIG. 8G such that an entire estimated frequency response H(f) can have a low-pass filter profile.

According to some embodiments of the present disclosure, a bandwidth of a detection channel can be obtained based on an estimated frequency response H(f) as shown in FIG. 8G. A bandwidth of a circuit may be defined as the frequency range over which a gain of the circuit is above 70.7% or −3 dB (where 0 dB is the maximum value) of its maximum output value. It is appreciated that an operation of a circuit is stable within the bandwidth. Referring back to FIG. 6, when diagnostic function 612 determines that the estimated bandwidth of a detection channel is not within a normal operation range, control signal generator 613 can generate a control signal to adjust a bandwidth of a detection channel.

According to some embodiments of the present disclosure, a detection channel bandwidth can be estimated during a self-diagnosis process (e.g., by diagnostic function 612 in FIG. 6). According to some embodiments of the present disclosure, a quantitative bandwidth estimation of a detection channel can be obtained after the whole system is built without relying on any dedicated test set up.

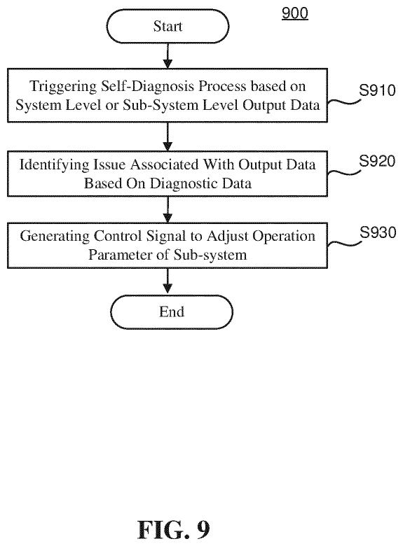

FIG. 9 illustrates a flow chart of an example self-diagnosis and calibration method, consistent with embodiments of the present disclosure. For illustrative purpose, a self-diagnosis and calibration method 900 will be described with respect to self-diagnosis and calibration system 600 of FIG. 6. In some embodiments, method 900 may be performed by system 600 of FIG. 6. In some embodiments, method 900 may be performed by a controller of the charged-particle inspection system (e.g., controller 109 of EBI system 100 in FIG. 1). The controller may include circuitry (e.g., a memory and a processor) programmed to implement method 900. For example, the controller may be an internal controller or an external controller (e.g., controller 109 in FIG. 1) coupled with the charged-particle inspection system.

In step S910, a self-diagnosis process is triggered based on system level output data or sub-system level output data. Step S910 can be performed by, for example, self-diagnosis trigger 611, among others. System level output data may include an inspection image of a sample to be inspected or a property(s) of an inspection image. A property(s) of an inspection image may include an image distortion degree, an image sharpness degree, image grey level, or an image contrast ratio, etc. In some embodiments, whether an inspection image or a property(s) of an inspection image meets a quality standard that may be preset for an inspection system or a sample. In some embodiments, a quality criterion of an inspection image may comprise a criterion related to an image distortion degree, an image sharpness degree, image grey level, or an image contrast ratio, etc. In some embodiments, a determination that an inspection image or inspection image property(s) is sub-standard may trigger a self-diagnosis process, consistent with some embodiments of the present disclosure.

Sub-system level output data may comprise output data of a sub-system or performance information of the output data of the sub-system. In some embodiments, sub-system level output data can be received from monitor 621 that is configured to collect output data of a sub-system or of each function block of the sub-system. In some embodiments, monitor 621 may be configured to collect real-time information of an operation status of a corresponding sub-system or a function block during a normal operation of an inspection system. In some embodiments, sub-system level output data may be collected by monitor 621 in real time during operation of an inspection system. In some embodiments, sub-system level output data may output data of a detection channel (e.g., detection system 500 of FIG. 5), each function block (e.g., sensor layer 301, analog signal path 510, or ADC 520 of FIG. 5) of a detection channel. In some embodiments, whether sub-system level output data or performance of the sub-system level output data meets an operation criterion is determined. In some embodiments, a determination that sub-system level output data or performance of the sub-system level output data do not meet an operation criterion may trigger a self-diagnosis process. In some embodiments, system level output data and sub-system level output data can be monitored together. By monitoring the system level output data and sub-system level output data together, which sub-system does not properly when an inspection image or inspection image property(s) is determined to be sub-standard. In some embodiments, a self-diagnosis process may be performed with respect to a sub-system(s) that does not meet an operation criterion.

In step S920, an issue associated with output data in step S910 can be identified based on diagnostic data of a sub-system of an inspection system. Step S920 can be performed by, for example, diagnostic function 612, among others. According to some embodiments, once a self-diagnosis process is triggered in step S910, step S920 can be initiated. In step S920, sub-components or sub-systems of inspection system 10 is diagnosed to determine what causes a defect of an inspection image or an operation defect of a sub-system, consistent with some embodiments of the present disclosure. In some embodiments, the sub-system that is not operating properly can be identified. According to some embodiments of the present disclosure, a self-diagnosis can be performed on data collected by diagnostic data collector 622. In some embodiments, diagnostic data collector 622 may start collecting data after a corresponding instruction is received from diagnostic function 612. In some embodiments, diagnostic data can be received from diagnostic data collector 622 that is embedded in an inspection system or electron beam tool associated with one or more components or sub-systems of an inspection system.

According to some embodiments, when a sub-system or a function block associated with the collected data operates properly in view of a preset standard, it can be determined that the sub-system (or function block) does not cause a performance issue. In some embodiments, a self-diagnosis can be performed on other sub-systems. When a sub-system or a function block associated with the collected data operates improperly in view of a present standard, it can be determined that the sub-system (or function block) is a root cause for a performance issue.

In some embodiments, diagnostic data may comprise, but is not limited to, primary beam fluctuation or profile information, beam aberration information, beam-limit aperture performance information, or detection channel performance information. In some embodiments, detection channel performance information can be associated with detection channel health and comprises, but not limited to, offset information or bandwidth information of the detection channel, performance information of an analog signal path, performance information of a converter included in the detection channel, or noise information of the detection channel. Analog signal path performance information may comprise, but is not limited to, operation point information, linearity information, gain information, bandwidth information, overshoot or undershoot information, or offset information of analog signal path 510. In some embodiments, ADC performance information may comprise offset information, linearity information, gain information, or bandwidth information of ADC 520.

In step S930, a control signal to adjust an operation parameter of a sub-system can be generated. Step S930 can be performed by, for example, control signal generator 613, among others. According to some embodiments, a control signal to perform a calibration to a sub-system or a function block can be generated based on a diagnosis result. In some embodiments, a control signal may be transmitted to an associated sub-system or function block to adjust parameters according to the control signal. In some embodiments, a control signal may be transmitted to calibrator 623 that is associated sub-system or function block to adjust parameters according to the control signal.

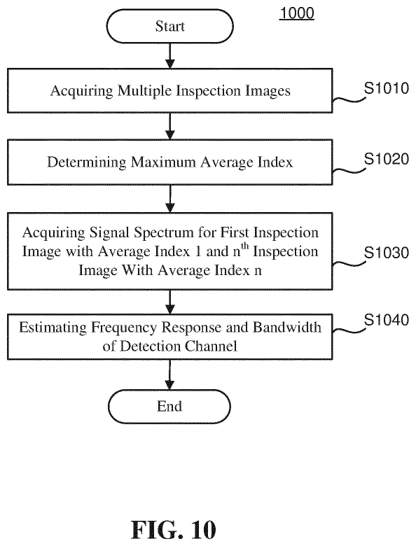

FIG. 10 illustrates a flow chart of an example detection channel bandwidth estimation method, consistent with embodiments of the present disclosure. For illustrative purpose, a detection channel bandwidth estimation method 1000 will be described with respect to bandwidth estimation apparatus 700 of FIG. 7. In some embodiments, method 1000 may be performed as a part of method 900 (e.g., step S930) of FIG. 9. In some embodiments, method 1000 may be performed by apparatus 700 of FIG. 7. In some embodiments, method 1000 may be performed by a controller of the charged-particle inspection system (e.g., controller 109 of EBI system 100 in FIG. 1). The controller may include circuitry (e.g., a memory and a processor) programmed to implement method 1000. For example, the controller may be an internal controller or an external controller (e.g., controller 109 in FIG. 1) coupled with the charged-particle inspection system.

In step S1010, multiple inspection images are acquired. Step S1010 can be performed by, for example, inspection image acquirer 710, among others. In some embodiments, an inspection image can be generated based on a detection signal from electron detection device 244 or 144 of electron beam tool 100. In some embodiments, multiple inspection images can be taken for a same pattern at a same location of a sample. In some embodiments, multiple inspection images may be obtained by an inspection system by using different average settings.

In step S1020, maximum average index is determined. Step S1020 can be performed by, for example, maximum average index determinator 720, among others. In step S1020, a highest average index from which increase of an average index does not improve inspection image sharpness or from which increase of an average index does not reduce blurriness can be determined. For example, if there is no sharpness improvement between a n−1^{th} inspection image and a n^{th} inspection image while there is sharpness improvement between a n−2^{th} inspection image and a n−1^{th} inspection image, the number n can be determined as a maximum average index.

In step S1030, signal spectrums corresponding to a first inspection image obtained with average index 1 and a n^{th} inspection image obtained with maximum average index n (e.g., nD1L1F) is acquired. Step S1030 can be performed by, for example, signal spectrum acquirer 720, among others. In some embodiments, a first time-domain signal can be acquired from a first inspection image obtained with average index 1. Similarly, a n^{th} time-domain signal can be acquired from a n^{th} inspection image obtained with maximum average index n. According to some embodiments, a signal spectrum for each of a first time-domain signal and a n^{th} time-domain signal can be obtained by a Fourier transform. A first signal spectrum S₁(f) corresponding to a first time-domain signal and a n^{th} signal spectrum Sₙ(f) corresponding to a n^{th} time-domain signal can be obtained.

In step S1040, a frequency response and a bandwidth of a detection channel can be estimated. Step S1040 can be performed by, for example, bandwidth estimator 740, among others. In some embodiments, a bandwidth of a detection channel can be estimated based on a first signal spectrum S₁(f) and an n^{th} signal spectrum Sₙ(f). As shown in FIG. 8B, an n^{th} spectral envelope function Eₙ(f) of an n^{th} signal spectrum Sₙ(f) can be acquired. As shown in FIG. 8C, a shifted n^{th} spectral envelope function Eₙ(f/n) of an n^{th} spectral envelope function Eₙ(f) can be obtained. A shift ratio (i.e., n) can be determined by the determined maximum average index, i.e., n. By shifting an n^{th} spectral envelope function Eₙ(f) by a ratio of a maximum average ratio to average index 1, a reference spectral envelope function Eₙ(f/n) that is within a same high frequency range as a first signal spectrum S₁(f) can be obtained, which is shown in FIG. 8D. As shown in FIG. 8E, a first spectral envelope function E₁(f) of a first spectrum S₁(f) can be acquired.

In some embodiments, a frequency response of a detection channel can be estimated based on a first spectral envelope function E₁(f) and a reference function, i.e., a shifted n^{th} spectral envelope function Eₙ(f/n). As shown in FIG. 8F, a partial estimated frequency response H(f) of a detection channel in a partial frequency range where first signal spectrum S₁(f) lies can be acquired by a ratio between a first spectral envelope function E₁(f) and a reference function, i.e., a shifted n^{th} spectral envelope function Eₙ(f/n) as H(f)=E₁(f)/Eₙ(f/n). It is appreciated that a frequency response of a detection channel is assumed to have a low-pass filter profile in a frequency domain in the present disclosure. Therefore, in some embodiments of the present disclosure, an entire estimated frequency response H(f) can be obtained by extending the constant response portion of a partial estimated frequency response H(f) for a lower frequency range, i.e., from frequency 0 to the point that a first spectral envelope function E₁(f) starts as shown in FIG. 8G such that an entire estimated frequency response H(f) can have a low-pass filter profile. According to some embodiments of the present disclosure, a bandwidth of a detection channel can be obtained based on an estimated frequency response H(f) as shown in FIG. 8G.

A non-transitory computer-readable medium may be provided that stores instructions for a processor of a controller (e.g., controller 109 in FIG. 1) for self-diagnosis and calibration methods and detection channel bandwidth estimation methods according to the exemplary flowchart of FIGS. 9 and 10, consistent with embodiments of the present disclosure. For example, the instructions stored in the non-transitory computer-readable medium may be executed by the circuitry of the controller for performing method 900 and 1000 in part or in entirety. Common forms of non-transitory media include, for example, a floppy disk, a flexible disk, hard disk, solid-state drive, magnetic tape, or any other magnetic data storage medium, a Compact Disc Read-Only Memory (CD-ROM), any other optical data storage medium, any physical medium with patterns of holes, a Random Access Memory (RAM), a Programmable Read-Only Memory (PROM), and Erasable Programmable Read-Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:

1. A method of performing a self-diagnosis of a charged particle inspection system, the method comprising:
triggering a self-diagnosis based on output data of the charged particle inspection system;
in response to the triggering of the self-diagnosis, receiving diagnostic data of a sub-system of the charged particle inspection system;
identifying an issue associated with the output data based on the diagnostic data of the sub-system;
and
generating a control signal to adjust an operation parameter of the sub-system according to the identified issue.

2. The method of clause 1, wherein the diagnostic data is obtained by a built-in hardware component of the charged particle inspection system.

3. The method of clause 2, wherein the built-in hardware component includes circuitry configured to generate a test signal and to gather the diagnostic data of the sub-system generated by the sub-system in response to the test signal.

4. The method of any one of clauses 1 to 3, wherein the output data includes system level output data, and wherein the system level output data includes an inspection image from the charged particle inspection system or a property of the inspection image.

5. The method of clause 4, wherein the property includes an image distortion degree, an image sharpness degree, image grey level, or an image contrast ratio.

6. The method of clause 4 or 5, wherein triggering the self-diagnosis comprises: determining whether the system level output data meets a criterion; and triggering the self-diagnosis in response to a determination that the system level output data does not meet the criterion.

7. The method of any one of clauses 1 to 3, wherein the output data includes sub-system level output data of the sub-system during operation of the charged particle inspection system or performance information of the sub-system level output data.

8. The method of clause 7, wherein triggering the self-diagnosis further comprises: determining whether the sub-system level output data or the performance information of the sub-system level output data meets a criterion; and triggering the self-diagnosis in response to a determination that the sub-system level output data or the performance information does not meet the criterion.

9. The method of clause 4, wherein the output data further includes sub-system level output data of the sub-system generated during operation of the charged particle inspection system or performance information of the sub-system level output data, and wherein triggering the self-diagnosis comprises: monitoring the system level output data and the sub-system level output data together; and triggering the self-diagnosis based on a monitoring result of the system level output data and the sub-system level output data.

10. The method of any one of clauses 1 to 9, wherein the diagnostic data includes primary beam fluctuation or profile information, beam aberration information, beam-limit aperture performance information, or detection channel performance information.

11. The method of clause 10, wherein the detection channel performance information includes offset information or bandwidth information of the detection channel, performance information of an analog signal path included in the detection channel, performance information of a converter included in the detection channel, or noise information of the detection channel.

12. The method of clause 10 or 11, wherein the detection channel includes a sensor layer comprising a sensing element, and wherein the analog signal path is configured to receive a signal representing an output of the sensor layer.

13. An apparatus of performing a self-diagnosis of a charged particle inspection system, the apparatus comprising: a memory storing a set of instructions; and at least one processor configured to execute the set of instructions to cause the apparatus to perform:
triggering a self-diagnosis based on output data of the charged particle inspection system;
in response to the triggering of the self-diagnosis, receiving diagnostic data of a sub-system of the charged particle inspection system; identifying an issue associated with the output data based on the diagnostic data of the sub-system; and generating a control signal to adjust an operation parameter of the sub-system according to the identified issue.

14. The apparatus of clause 13, wherein the diagnostic data is obtained by a built-in hardware component of the charged particle inspection system.

15. The apparatus of clause 14, wherein the built-in hardware component includes circuitry configured to generate a test signal and to gather the diagnostic data of the sub-system generated by the sub-system in response to the test signal.

16. The apparatus of any one of clauses 13 to 15, wherein the output data includes system level output data, and wherein the system level output data includes an inspection image from the charged particle inspection system or a property of the inspection image.

17. The apparatus of clause 16, wherein the property includes an image distortion degree, an image sharpness degree, image grey level, or an image contrast ratio.

18. The apparatus of clause 16 or 17, wherein, in triggering the self-diagnosis, the at least one processor is configured to execute the set of instructions to cause the apparatus to further perform: determining whether the system level output data meets a criterion; and triggering the self-diagnosis in response to a determination that the system level output data does not meet the criterion.

19. The apparatus of any one of clauses 13-15, wherein the output data includes sub-system level output data of the sub-system during operation of the charged particle inspection system or performance information of the sub-system level output data.

20. The apparatus of clause 19, wherein, in triggering the self-diagnosis, the at least one processor is configured to execute the set of instructions to cause the apparatus to further perform: determining whether the sub-system level output data or the performance information of the sub-system level output data meets a criterion; and triggering the self-diagnosis in response to a determination that the sub-system level output data or the performance information does not meet the criterion.

21. The apparatus of clause 16, wherein the output data further includes sub-system level output data of the sub-system generated during operation of the charged particle inspection system or performance information of the sub-system level output data, and
wherein, in triggering the self-diagnosis, the at least one processor is configured to execute the set of instructions to cause the apparatus to further perform:
monitoring the system level output data and the sub-system level output data together; and triggering the self-diagnosis based on a monitoring result of the system level output data and the sub-system level output data.

22. The apparatus of any one of clauses 13 to 21, wherein the diagnostic data includes primary beam fluctuation or profile information, beam aberration information, beam-limit aperture performance information, or detection channel performance information.

23. The apparatus of clause 22, wherein the detection channel performance information includes offset information or bandwidth information of the detection channel, performance information of an analog signal path included in the detection channel, performance information of a converter included in the detection channel, or noise information of the detection channel.

24. The apparatus of clause 22 or 23, wherein the detection channel includes a sensor layer comprising a sensing element, and wherein the analog signal path is configured to receive a signal representing an output of the sensor layer.

25. A non-transitory computer readable medium that stores a set of instructions that is executable by at least one processor of a computing device to cause the computing device to perform a method of performing a self-diagnosis of a charged particle inspection system, the method comprising:
triggering a self-diagnosis based on output data of the charged particle inspection system; in response to the triggering of the self-diagnosis, receiving diagnostic data of a sub-system of the charged particle inspection system;
identifying an issue associated with the output data based on the diagnostic data of the sub-system; and generating a control signal to adjust an operation parameter of the sub-system according to the identified issue.

26. The computer readable medium of clause 25, wherein the diagnostic data is obtained by a built-in hardware component of the charged particle inspection system.

27. The computer readable medium of clause 26, wherein the built-in hardware component includes circuitry configured to generate a test signal and to gather the diagnostic data of the sub-system generated by the sub-system in response to the test signal.

28. The computer readable medium of any one of clauses 25-27, wherein the output data includes system level output data, and wherein the system level output data includes an inspection image from the charged particle inspection system or a property of the inspection image.

29. The computer readable medium of clause 28, wherein the property includes an image distortion degree, an image sharpness degree, image grey level, or an image contrast ratio.

30. The computer readable medium of clause 28 or 29, wherein, in triggering the self-diagnosis, the set of instructions that is executable by at least one processor of the computing device cause the computing device to further perform:
determining whether the system level output data meets a criterion; and triggering the self-diagnosis in response to a determination that the system level output data does not meet the criterion.

31. The computer readable medium of any one of clauses 25-27, wherein the output data includes sub-system level output data of the sub-system during operation of the charged particle inspection system or performance information of the sub-system level output data.

32. The computer readable medium of clause 31, wherein, in triggering the self-diagnosis, the set of instructions that is executable by at least one processor of the computing device cause the computing device to further perform: determining whether the sub-system level output data or the performance information of the sub-system level output data meets a criterion; and triggering the self-diagnosis in response to a determination that the sub-system level output data or the performance information does not meet the criterion.

33. The computer readable medium of clause 28, wherein the output data further includes sub-system level output data of the sub-system generated during operation of the charged particle inspection system or performance information of the sub-system level output data, and wherein, in triggering the self-diagnosis, the set of instructions that is executable by at least one processor of the computing device cause the computing device to further perform:
monitoring the system level output data and the sub-system level output data together; and triggering the self-diagnosis based on a monitoring result of the system level output data and the sub-system level output data.

34. The computer readable medium of any one of clauses 25 to 33, wherein the diagnostic data includes primary beam fluctuation or profile information, beam aberration information, beam-limit aperture performance information, or detection channel performance information.

35. The computer readable medium of clause 34, wherein the detection channel performance information includes offset information or bandwidth information of the detection channel, performance information of an analog signal path included in the detection channel, performance information of a converter included in the detection channel, or noise information of the detection channel.

36. The computer readable medium of clause 34 or 35, wherein the detection channel includes a sensor layer comprising a sensing element, and wherein the analog signal path is configured to receive a signal representing an output of the sensor layer.

37. A method of estimating a bandwidth of a detection channel of a charged particle inspection system, the method comprising: acquiring multiple inspection images of a sample, the multiple inspection images being obtained using different average indexes;
determining a maximum average index from which an increase of an average index does not contribute to inspection image sharpness;
acquiring a first signal corresponding to a first inspection image among the multiple inspection images and a second signal corresponding to a second inspection image among the multiple inspection images, wherein the first inspection image is obtained using average index 1 and the second inspection image is obtained using the maximum average index;
acquiring a first signal spectrum of the first signal and a second signal spectrum of the second signal;
acquiring a shifted second signal spectrum with a ratio of the maximum average index, wherein the shifted second signal spectrum and the first signal spectrum are distributed in a same frequency range;
and acquiring an estimated partial frequency response of the detection channel based on the first signal spectrum and the shifted second signal spectrum.

38. The method of clause 37, further comprising:
acquiring an estimated entire frequency response based on the estimated partial frequency response;
and estimating a bandwidth of the detection channel.

39. The method of clause 37 or 38, further comprising:
acquiring a first envelope function corresponding to the first signal spectrum and a shifted second envelope function corresponding to the shifted second signal spectrum.

40. The method of clause 39, wherein the estimated partial frequency response is obtained based on a ratio of the first envelope function to the shifted second envelope function.

41. The method of any one of clauses 37 to 40, wherein the detection channel comprises: a sensor layer comprising a sensing element; an analog signal path configured to receive a signal representing an output of the sensor layer; and a converter configured to convert an output of the analog signal path to a digital signal.

42. An apparatus estimating a bandwidth of a detection channel of a charged particle inspection system, the apparatus comprising: a memory storing a set of instructions; and
at least one processor configured to execute the set of instructions to cause the apparatus to perform: acquiring multiple inspection images of a sample, the multiple inspection images being obtained using different average indexes; determining a maximum average index from which an increase of an average index does not contribute to inspection image sharpness; acquiring a first signal corresponding to a first inspection image among the multiple inspection images and a second signal corresponding to a second inspection image among the multiple inspection images, wherein the first inspection image is obtained using average index 1 and the second inspection image is obtained using the maximum average index; acquiring a first signal spectrum of the first signal and a second signal spectrum of the second signal; acquiring a shifted second signal spectrum with a ratio of the maximum average index, wherein the shifted second signal spectrum and the first signal spectrum are distributed in a same frequency range; and acquiring an estimated partial frequency response of the detection channel based on the first signal spectrum and the shifted second signal spectrum.

43. The apparatus of clause 42, wherein the at least one processor is configured to execute the set of instructions to cause the apparatus to further perform:
acquiring an estimated entire frequency response based on the estimated partial frequency response; and estimating a bandwidth of the detection channel.

44. The apparatus of clause 42 or 43, wherein the at least one processor is configured to execute the set of instructions to cause the apparatus to further perform: acquiring a first envelope function corresponding to the first signal spectrum and a shifted second envelope function corresponding to the shifted second signal spectrum.

45. The apparatus of clause 44, wherein the estimated partial frequency response is obtained based on a ratio of the first envelope function to the shifted second envelope function.

46. The apparatus of any one of clauses 42 to 45, wherein the detection channel comprises: a sensor layer comprising a sensing element; an analog signal path configured to receive a signal representing an output of the sensor layer; and a converter configured to convert an output of the analog signal path to a digital signal.

47. A non-transitory computer readable medium that stores a set of instructions that is executable by at least one processor of a computing device to cause the computing device to perform a method of estimating a bandwidth of a detection channel of a charged particle inspection system, the method comprising: acquiring multiple inspection images of a sample, the multiple inspection images being obtained using different average indexes; determining a maximum average index from which an increase of an average index does not contribute to inspection image sharpness;
acquiring a first signal corresponding to a first inspection image among the multiple inspection images and a second signal corresponding to a second inspection image among the multiple inspection images, wherein the first inspection image is obtained using average index 1 and the second inspection image is obtained using the maximum average index;
acquiring a first signal spectrum of the first signal and a second signal spectrum of the second signal; acquiring a shifted second signal spectrum with a ratio of the maximum average index, wherein the shifted second signal spectrum and the first signal spectrum are distributed in a same frequency range;
and acquiring an estimated partial frequency response of the detection channel based on the first signal spectrum and the shifted second signal spectrum.

48. The computer readable medium of clause 47, wherein the set of instructions that is executable by at least one processor of the computing device cause the computing device to further perform: acquiring an estimated entire frequency response based on the estimated partial frequency response; and estimating a bandwidth of the detection channel.

49. The computer readable medium of clause 47 or 48, wherein the set of instructions that is executable by at least one processor of the computing device cause the computing device to further perform: acquiring a first envelope function corresponding to the first signal spectrum and a shifted second envelope function corresponding to the shifted second signal spectrum.

50. The computer readable medium of clause 49, wherein the estimated partial frequency response is obtained based on a ratio of the first envelope function to the shifted second envelope function.

51. The computer readable medium of any one of clauses 47 to 50, wherein the detection channel comprises: a sensor layer comprising a sensing element; an analog signal path configured to receive a signal representing an output of the sensor layer; and a converter configured to convert an output of the analog signal path to a digital signal.

52. An apparatus of performing a self-diagnosis of a charged particle inspection system, the apparatus comprising: a memory storing a set of instructions; and at least one processor configured to execute the set of instructions to cause the apparatus to perform:
triggering a self-diagnosis based on output data of the charged particle inspection system;
in response to the triggering of the self-diagnosis, receiving diagnostic data of a detection channel of the charged particle inspection system; estimating a bandwidth of the detection channel based on the diagnostic data; and generating a control signal to adjust an operation parameter associated with the detection channel based on the estimated bandwidth.

53. The apparatus of clause 52, wherein the diagnostic data comprises:
multiple inspection images of a sample, the multiple inspection images being obtained using different average indexes; a first signal corresponding to a first inspection image among the multiple inspection images; and a second signal corresponding to a second inspection image among the multiple inspection images, wherein the first inspection image is obtained using average index 1 and the second inspection image is obtained using a maximum average index from which an increase of an average index does not contribute to inspection image sharpness, and wherein the first signal and the second signal are output signals of the detection channel.

54. The apparatus of clause 53, wherein, in estimating the bandwidth, at least one processor is configured to execute the set of instructions to cause the apparatus to further perform: determining the maximum average index; acquiring a first signal spectrum of the first signal and a second signal spectrum of the second signal; acquiring a shifted second signal spectrum with a ratio of the maximum average index, wherein the shifted second signal spectrum and the first signal spectrum are distributed in a same frequency range; and acquiring an estimated partial frequency response of the detection channel based on the first signal spectrum and the shifted second signal spectrum.

55. The apparatus of clause 54, wherein, in estimating the bandwidth, the at least one processor is configured to execute the set of instructions to cause the apparatus to further perform: acquiring an estimated entire frequency response based on the estimated partial frequency response; and estimating the bandwidth of the detection channel based on the estimated entire frequency response.

56. The apparatus of clause 54 or 55, wherein, in estimating a bandwidth, the at least one processor is configured to execute the set of instructions to cause the apparatus to further perform: acquiring a first envelope function corresponding to the first signal spectrum and a shifted second envelope function corresponding to the shifted second signal spectrum.

57. The apparatus of clause 56, wherein the estimated partial frequency response is obtained based on a ratio of the first envelope function to the shifted second envelope function.

58. The apparatus of any one of clauses 52 to 57, wherein the detection channel comprises: a sensor layer comprising a plurality of sensing elements; an analog signal path configured to receive a signal representing an output of the sensor layer; and a converter configured to convert an output of the analog signal path to a digital signal.

59. The apparatus of any one of clauses 52 to 58, wherein the diagnostic data is obtained by a built-in hardware component of the charged particle inspection system.

Block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes can be made without departing from the scope thereof. For example, a charged particle inspection system may be but one example of a charged particle beam system consistent with embodiments of the present disclosure.

1. An apparatus of performing a self-diagnosis of a charged particle inspection system, the apparatus comprising:
a memory storing a set of instructions; and
at least one processor configured to execute the set of instructions to cause the apparatus to perform:
triggering a self-diagnosis based on output data of the charged particle inspection system;
in response to the triggering of the self-diagnosis, receiving diagnostic data of a sub-system of the charged particle inspection system;
identifying an issue associated with the output data based on the diagnostic data of the sub-system; and
generating a control signal to adjust an operation parameter of the sub-system according to the identified issue.

2. The apparatus of claim 1, wherein the diagnostic data is obtained by a built-in hardware component of the charged particle inspection system.

3. The apparatus of claim 2, wherein the built-in hardware component includes circuitry configured to generate a test signal and to gather the diagnostic data of the sub-system generated by the sub-system in response to the test signal.

4. The apparatus of claim 1, wherein the output data includes system level output data, and wherein the system level output data includes an inspection image from the charged particle inspection system or a property of the inspection image.

5. The apparatus of claim 4, wherein the property includes an image distortion degree, an image sharpness degree, image grey level, or an image contrast ratio.

6. The apparatus of claim 4, wherein, in triggering the self-diagnosis, the at least one processor is configured to execute the set of instructions to cause the apparatus to further perform:
determining whether the system level output data meets a criterion; and
triggering the self-diagnosis in response to a determination that the system level output data does not meet the criterion.

7. The apparatus of claim 1, wherein the output data includes sub-system level output data of the sub-system during operation of the charged particle inspection system or performance information of the sub-system level output data.

8. The apparatus of claim 7, wherein, in triggering the self-diagnosis, the at least one processor is configured to execute the set of instructions to cause the apparatus to further perform:
determining whether the sub-system level output data or the performance information of the sub-system level output data meets a criterion; and
triggering the self-diagnosis in response to a determination that the sub-system level output data or the performance information does not meet the criterion.

9. The apparatus of claim 4, wherein the output data further includes sub-system level output data of the sub-system generated during operation of the charged particle inspection system or performance information of the sub-system level output data, and
wherein, in triggering the self-diagnosis, the at least one processor is configured to execute the set of instructions to cause the apparatus to further perform:
monitoring the system level output data and the sub-system level output data together; and
triggering the self-diagnosis based on a monitoring result of the system level output data and the sub-system level output data.

10. The apparatus of claim 1, wherein the diagnostic data includes primary beam fluctuation or profile information, beam aberration information, beam-limit aperture performance information, or detection channel performance information.

11. The apparatus of claim 10, wherein the detection channel performance information includes offset information or bandwidth information of the detection channel, performance information of an analog signal path included in the detection channel, performance information of a converter included in the detection channel, or noise information of the detection channel.

12. The apparatus of claim 11, wherein the detection channel includes a sensor layer comprising a sensing element, and
wherein the analog signal path is configured to receive a signal representing an output of the sensor layer.

13. A non-transitory computer readable medium that stores a set of instructions that is executable by at least one processor of a computing device to cause the computing device to perform a method of performing a self-diagnosis of a charged particle inspection system, the method comprising:
triggering a self-diagnosis based on output data of the charged particle inspection system;
in response to the triggering of the self-diagnosis, receiving diagnostic data of a sub-system of the charged particle inspection system;
identifying an issue associated with the output data based on the diagnostic data of the sub-system; and
generating a control signal to adjust an operation parameter of the sub-system according to the identified issue.

14. The computer readable medium of claim 13, wherein the output data includes system level output data, and
wherein the system level output data includes an inspection image from the charged particle inspection system or a property of the inspection image.

15. The computer readable medium of claim 14, wherein, in triggering the self-diagnosis, the set of instructions that is executable by at least one processor of the computing device cause the computing device to further perform:
determining whether the system level output data meets a criterion; and
triggering the self-diagnosis in response to a determination that the system level output data does not meet the criterion.

16. An apparatus estimating a bandwidth of a detection channel of a charged particle inspection system, the apparatus comprising:
a memory storing a set of instructions; and
at least one processor configured to execute the set of instructions to cause the apparatus to perform:
acquiring multiple inspection images of a sample, the multiple inspection images being obtained using different average indexes;
determining a maximum average index from which an increase of an average index does not contribute to inspection image sharpness;
acquiring a first signal corresponding to a first inspection image among the multiple inspection images and a second signal corresponding to a second inspection image among the multiple inspection images, wherein the first inspection image is obtained using average index 1 and the second inspection image is obtained using the maximum average index;
acquiring a first signal spectrum of the first signal and a second signal spectrum of the second signal;
acquiring a shifted second signal spectrum with a ratio of the maximum average index, wherein the shifted second signal spectrum and the first signal spectrum are distributed in a same frequency range; and
acquiring an estimated partial frequency response of the detection channel based on the first signal spectrum and the shifted second signal spectrum.

17. The apparatus of claim 16, wherein the at least one processor is configured to execute the set of instructions to cause the apparatus to further perform:
acquiring an estimated entire frequency response based on the estimated partial frequency response; and estimating a bandwidth of the detection channel.

18. The apparatus of claim 16, wherein the at least one processor is configured to execute the set of instructions to cause the apparatus to further perform:
acquiring a first envelope function corresponding to the first signal spectrum and a shifted second envelope function corresponding to the shifted second signal spectrum.

19. The apparatus of claim 18, wherein the estimated partial frequency response is obtained based on a ratio of the first envelope function to the shifted second envelope function.

20. The apparatus of claim 16, wherein the detection channel comprises:
a sensor layer comprising a sensing element; an analog signal path configured to receive a signal representing an output of the sensor layer; and a converter configured to convert an output of the analog signal path to a digital signal.
